(19) United States
(12) Patent Application Publication
(10) Pub. No.: US 2023/0101309 A1
(43) Pub. Date: Mar. 30, 2023

(54) IMAGING ELEMENT AND IMAGING DEVICE

(71) Applicant: Sony Group Corporation, Tokyo (JP)

(72) Inventors: Masato KANNO, Tokyo (JP); Chiaki TAKAHASHI, Tokyo (JP); Yosuke SAITO, Tokyo (JP)

(21) Appl. No.: 17/794,746

(22) PCT Filed: Jan. 18, 2021
(86) PCT No.: PCT/JP2021/001393

§ 371 Date: Jul. 22, 2022

(30) Foreign Application Priority Data
Jan. 29, 2020 (JP) 2020-012779

(51) Int. Cl. H01L 51/42; H01L 51/44; H01L 31/0224

(52) U.S. Cl. CPC H01L 51/4213; H01L 51/441; H01L 31/022408

(57) ABSTRACT

An imaging element according to an embodiment of the present disclosure includes: a first electrode; a second electrode; an organic layer; a first semiconductor layer; and a second semiconductor layer. The second electrode is disposed to be opposed to the first electrode. The organic layer is provided between the first electrode and the second electrode. The organic layer includes at least a photoelectric conversion layer. The first semiconductor layer is provided between the second electrode and the organic layer. The first semiconductor layer includes at least one of a carbon-containing compound or an inorganic compound. The carbon-containing compound has a greater electron affinity than a work function of the first electrode. The inorganic compound has a greater work function than the work function of the first electrode. The second semiconductor layer is provided between the second electrode and the first semiconductor layer. The second semiconductor layer has an absolute value B of a difference between a HOMO (Highest Occupied Molecular Orbital) level and a Fermi level of the second electrode or has, near the Fermi level, an in-gap level having a state density of 1/10000 or more as compared with the HOMO level. The absolute value B is greater than or equal to an absolute value A of a difference between a first LUMO (Lowest Unoccupied Molecular Orbital) level and the Fermi level. The first LUMO level is calculated from an optical band gap.

### TECHNICAL FIELD

The present disclosure relates to an imaging element in which, for example, an organic material is used and an imaging device including the imaging element.

### BACKGROUND ART

In recent years, there has been proposed a so-called vertical spectroscopic imaging element having a vertical multilayer structure in which an organic photoelectric conversion section is disposed above a semiconductor substrate. In the vertical spectroscopic imaging element, pieces of light in the red and blue wavelength ranges are photoelectrically converted by respective photoelectric conversion sections (photodiodes PD1 and PD2) formed in a semiconductor substrate and light in the green wavelength range is photoelectrically converted by an organic photoelectric conversion film provided to an organic photoelectric conversion section.

In such an imaging element, the electric charge generated through photoelectric conversion by the photodiodes PD1 and PD2 is temporarily accumulated in the photodiodes PD1 and PD2 and then transferred to respective floating diffusion layers. This makes it possible to fully deplete the photodiodes PD1 and PD2. Meanwhile, the electric charge generated by the organic photoelectric conversion section is directly accumulated in a floating diffusion layer. This makes it difficult to fully deplete the organic photoelectric conversion section, thereby increasing kTC noise and degenerating random noise. This leads to lower image quality in imaging.

In contrast, for example, PTL 1 discloses an imaging element provided with an electrode for electric charge accumulation in a photoelectric conversion section that is provided on a semiconductor substrate and includes a first electrode, a photoelectric conversion layer, and a second electrode which are stacked, thereby suppress a decrease in image quality in imaging. The electrode for electric charge accumulation is disposed to be spaced apart from the first electrode and opposed to the photoelectric conversion layer with an insulating layer interposed in between.

### CITATION LIST

### Patent Literature

PTL 1: Japanese Unexamined Patent Application Publication No. 2017-157816

### SUMMARY OF THE INVENTION

Incidentally, an imaging element is requested to have higher photoresponsivity.

It is desirable to provide an imaging element and an imaging device each of which makes it possible to increase the photoresponsivity.

An imaging element according to an embodiment of the present disclosure includes: a first electrode; a second electrode; an organic layer; a first semiconductor layer; and a second semiconductor layer. The second electrode is disposed to be opposed to the first electrode. The organic layer is provided between the first electrode and the second electrode. The organic layer includes at least a photoelectric conversion layer. The first semiconductor layer is provided between the second electrode and the organic layer. The first semiconductor layer includes at least one of a carbon-containing compound or an inorganic compound. The carbon-containing compound has a greater electron affinity than a work function of the first electrode. The inorganic compound has a greater work function than the work function of the first electrode. The second semiconductor layer is provided between the second electrode and the first semiconductor layer. The second semiconductor layer has an absolute value B of a difference between a HOMO (Highest Occupied Molecular Orbital) level and a Fermi level of the second electrode or has, near the Fermi level, an in-gap level having a state density of 1/10000 or more as compared with the HOMO level. The absolute value B is greater than or equal to an absolute value A of a difference between a first LUMO (Lowest Unoccupied Molecular Orbital) level and the Fermi level. The first LUMO level is calculated from an optical band gap.

An imaging device according to an embodiment of the present disclosure includes the one or more imaging elements according to the embodiment of the present disclosure described above for each of a plurality of pixels.

The imaging element according to the embodiment of the present disclosure and the imaging device according to the embodiment are each provided with the first semiconductor layer between the second electrode and the organic layer. The second electrode is disposed to be opposed to the first electrode with the organic layer interposed in between. The organic layer includes at least the photoelectric conversion layer. The first semiconductor layer includes at least one of the carbon-containing compound or the inorganic compound. The carbon-containing compound has a greater electron affinity than the work function of the first electrode. The inorganic compound has a greater work function than the work function of the first electrode. Further, the imaging element according to the embodiment of the present disclosure and the imaging device according to the embodiment are each provided with the second semiconductor layer between the second electrode and the first semiconductor layer. The second semiconductor layer has the absolute value B of the difference between the HOMO level and the Fermi level of the second electrode or has, near the Fermi level, the in-gap level having a state density of 1/10000 or more as compared with the HOMO level. The absolute value B is greater than or equal to the absolute value A of the difference between the first LUMO level and the Fermi level. The first LUMO level is calculated from the optical band gap. This promotes electrons to be injected from the second electrode to the first semiconductor layer.

### BRIEF DESCRIPTION OF DRAWING

FIG. 1 is a cross-sectional schematic diagram illustrating an example of a schematic configuration of an imaging element according to an embodiment of the present disclosure.

FIG. 2 is an equivalent circuit diagram of the imaging element illustrated in FIG. 1.

FIG. 3 is a schematic diagram illustrating disposition of a lower electrode and a transistor included in a controller of an organic photoelectric conversion section illustrated in FIG. 1.

FIG. 4A is a diagram illustrating an example of an energy level of the organic photoelectric conversion section illustrated in FIG. 1.

FIG. 4B is a diagram illustrating another example of the energy level of the organic photoelectric conversion section illustrated in FIG. 1.

FIG. 5 is a diagram illustrating a measurement result of each of energy levels of NBphen.

FIG. 6 is a diagram illustrating a measurement result of each of energy levels of NDI35.

FIG. 7 is a cross-sectional view for describing a method of manufacturing the imaging element illustrated in FIG. 1.

FIG. 8 is a cross-sectional view of a step subsequent to FIG. 7.

FIG. 9 is a cross-sectional view of a step subsequent to FIG. 8.

FIG. 10 is a cross-sectional view of a step subsequent to FIG. 9.

FIG. 11 is a cross-sectional view of a step subsequent to FIG. 10.

FIG. 12 is a cross-sectional view of a step subsequent to FIG. 11.

FIG. 13 is a cross-sectional view of a step subsequent to FIG. 12.

FIG. 14 is a timing chart illustrating an operation example of the imaging element illustrated in FIG. 1.

FIG. 15 is a block diagram illustrating a configuration of an imaging device in which the imaging element illustrated in FIG. 1 is used as a pixel.

FIG. 16 is a functional block diagram illustrating an example of an electronic apparatus (camera) in which the imaging device illustrated in FIG. 15 is used.

FIG. 17 is a block diagram depicting an example of a schematic configuration of an in-vivo information acquisition system.

FIG. 18 is a view depicting an example of a schematic configuration of an endoscopic surgery system.

FIG. 19 is a block diagram depicting an example of a functional configuration of a camera head and a camera control unit (CCU).

FIG. 20 is a block diagram depicting an example of schematic configuration of a vehicle control system.

FIG. 21 is a diagram of assistance in explaining an example of installation positions of an outside-vehicle information detecting section and an imaging section.

FIG. 22 is a cross-sectional schematic diagram illustrating a device structure as an evaluation sample.

### MODES FOR CARRYING OUT THE INVENTION

The following describes an embodiment of the present disclosure in detail with reference to the drawings. The following description is a specific example of the present disclosure, but the present disclosure is not limited to the following modes. In addition, the present disclosure is not also limited to the disposition, dimensions, dimension ratios, and the like of the respective components illustrated in the respective diagrams. It is to be noted that description is given in the following order.

1. Embodiment (an example in which an electron injection promoting layer having a predetermined energy level is provided between a work function adjustment layer and an upper electrode)

### 1-1. Configuration of Imaging Element

### 1-2. Method of Manufacturing Imaging Element

### 1-3. Workings and Effects

### 2. Application Examples

### 3. Practical Application Examples

### 4. Working Examples

### 1. EMBODIMENT

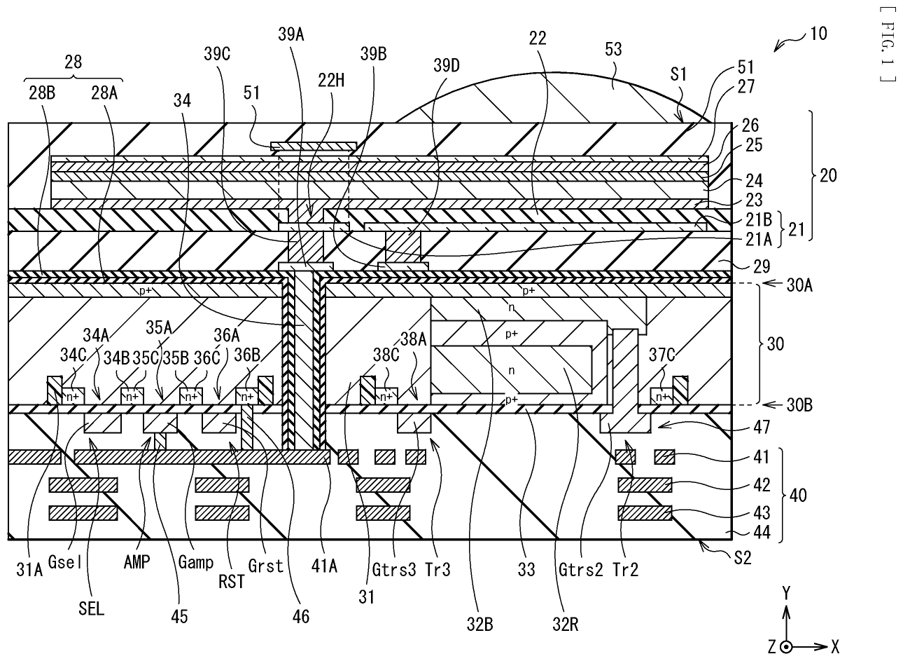

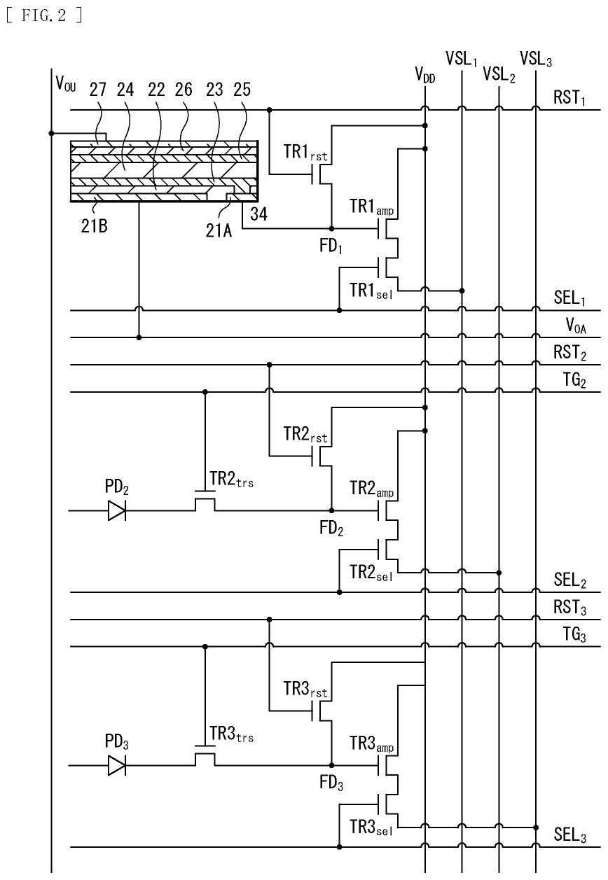

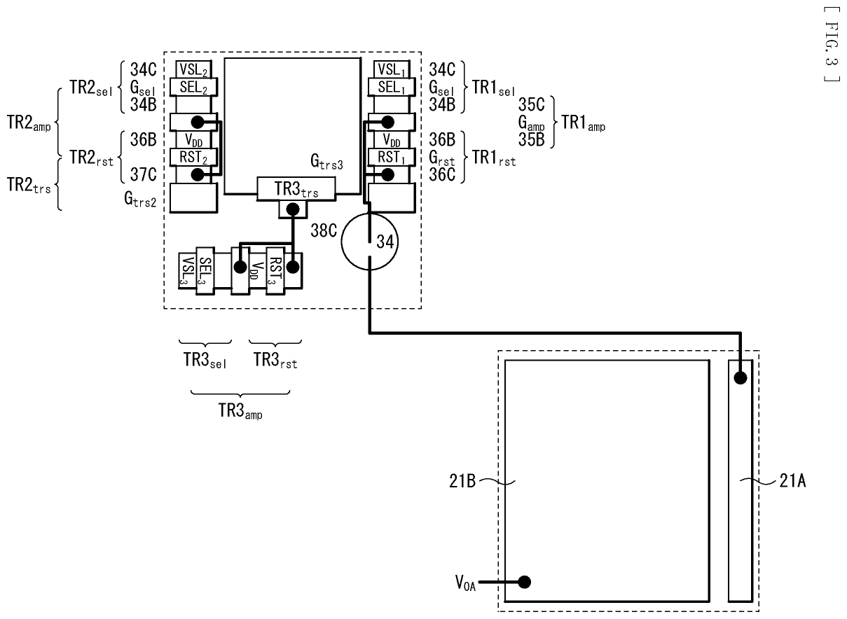

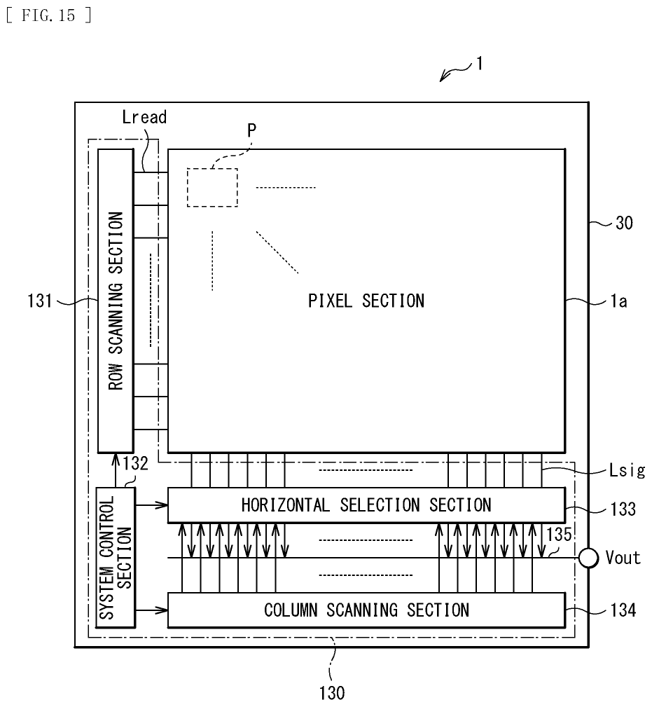

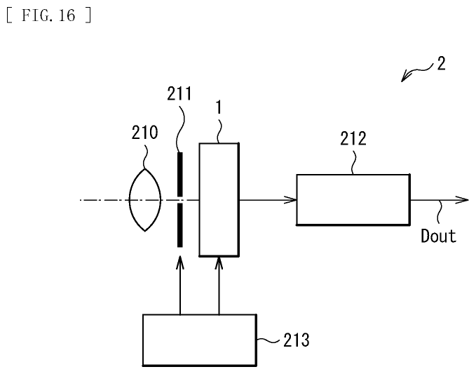

FIG. 1 illustrates a cross-sectional configuration of an imaging element (imaging element 10) according to an embodiment of the present disclosure. FIG. 2 is an equivalent circuit diagram of the imaging element 10 illustrated in FIG. 1. FIG. 3 schematically illustrates the disposition of a lower electrode 21 and a transistor included in a controller of the imaging element 10 illustrated in FIG. 1. The imaging element 10 is included, for example, in one pixel (unit pixel P) of an imaging device (imaging device 1; see FIG. 15) such as a CMOS (Complementary Metal Oxide Semiconductor) image sensor used for an electronic apparatus such as a digital still camera or a video camera. The imaging element 10 according to the present embodiment is provided with a work function adjustment layer 25 (first semiconductor layer) between a photoelectric conversion layer 24 and an upper electrode 27 (second electrode) and an electron injection promoting layer 26 (second semiconductor layer) between the upper electrode 27 and the work function adjustment layer 25 in an organic photoelectric conversion section 20 provided above a semiconductor substrate 30. The work function adjustment layer 25 (first semiconductor layer) has a predetermined work function or an electron affinity. The electron injection promoting layer 26 (second semiconductor layer) has a predetermined energy level.

### 1-1. Configuration of Imaging Element

The imaging element 10 is a so-called vertical spectroscopic imaging element in which the one organic photoelectric conversion section 20 and two inorganic photoelectric conversion sections 32B and 32R are stacked in the vertical direction. The organic photoelectric conversion section 20 is provided on a first surface (back surface) 30A side of the semiconductor substrate 30. The inorganic photoelectric conversion sections 32B and 32R are formed to be buried in the semiconductor substrate 30 and stacked in the thickness direction of the semiconductor substrate 30. The organic photoelectric conversion section 20 includes the photoelectric conversion layer 24 between the lower electrode 21 (first electrode) and the upper electrode 27 that are disposed to be opposed to each other. The photoelectric conversion layer 24 is formed by using an organic material. The photoelectric conversion layer 24 includes a p-type semiconductor and an n-type semiconductor and has a bulk heterojunction structure in the layer. The bulk heterojunction structure is a p/n junction surface formed by mixing a p-type semiconductor and an n-type semiconductor.

The organic photoelectric conversion section 20 and the inorganic photoelectric conversion sections 32B and 32R perform photoelectric conversion by selectively detecting respective pieces of light in different wavelength ranges. Specifically, the organic photoelectric conversion section 20 acquires, for example, a color signal of green (G). The inorganic photoelectric conversion sections 32B and 32R respectively acquire, for example, a color signal of blue (B) and a color signal of red (R) by using a difference between absorption coefficients. This allows the imaging element 10 to acquire a plurality of types of color signals in one pixel without using any color filter.

It is to be noted that, in the present embodiment, a case is described where the electron of an electron-hole pair (exciton) generated through photoelectric conversion is read out as signal charge. In other words, a case is described where the n-type semiconductor region is used as a photoelectric conversion layer. In addition, in the drawings, “+ (plus)” attached to “p” and “n” indicates a high p-type or n-type impurity concentration.

A second surface (front surface) 30B of the semiconductor substrate 30 is provided, for example, with floating diffusions (floating diffusion layers) FD1 (a region 36B in the semiconductor substrate 30), FD2 (a region 37C in the semiconductor substrate 30), and FD3 (a region 38C in the semiconductor substrate 30), transfer transistors Tr2 and Tr3, an amplifier transistor (modulation element) AMP, a reset transistor RST, a selection transistor SEL, and a multilayer wiring layer 40. The multilayer wiring layer 40 has, for example, a configuration in which wiring layers 41, 42, and 43 are stacked in an insulating layer 44.

It is to be noted that the diagram illustrates the first surface 30A side of the semiconductor substrate 30 as a light incidence side S1, and the second surface 30B side thereof as a wiring layer side S2.

The organic photoelectric conversion section 20 has a configuration in which the lower electrode 21, an electric charge accumulation layer 23, the photoelectric conversion layer 24, the work function adjustment layer 25, the electron injection promoting layer 26, and the upper electrode 27 are stacked in this order from the first surface 30A side of the semiconductor substrate 30. In addition, there is provided an insulating layer 22 between the lower electrode 21 and the electric charge accumulation layer 23. For example, the lower electrodes 21 are formed separately for the respective imaging elements 10. Although described below in detail, the lower electrodes 21 each include a readout electrode 21A and an accumulation electrode 21B that are separated from each other with the insulating layer 22 interposed in between. The readout electrode 21A of the lower electrode 21 is electrically coupled to the photoelectric conversion layer 24 through an opening 22H provided in the insulating layer 22. FIG. 1 illustrates an example in which the electric charge accumulation layers 23, the photoelectric conversion layers 24, the work function adjustment layers 25, and the upper electrodes 27 are separately formed for the respective imaging elements 10. For example, the electric charge accumulation layer 23, the photoelectric conversion layer 24, the work function adjustment layer 25, and the upper electrode 27 may be, however, formed as continuous layers common to the plurality of imaging elements 10.

For example, there are provided an insulating layer 28 and an interlayer insulating layer 29 between the first surface 30A of the semiconductor substrate 30 and the lower electrode 21. The insulating layer 28 includes a layer (fixed electric charge layer) 28A having fixed electric charge and a dielectric layer 28B having an insulation property. There is provided a protective layer 51 on the upper electrode 27. There is provided a light shielding film 52, for example, above the readout electrode 21A in the protective layer 51. It is sufficient if this light shielding film 52 is provided to cover at least the region of the readout electrode 21A in direct contact with the photoelectric conversion layer 24 without overlapping with at least the accumulation electrode 21B. There are provided optical members such as a planarization layer (not illustrated) and an on-chip lens 53 above the protective layer 51.

There is provided a through electrode 34 between the first surface 30A and the second surface 30B of the semiconductor substrate 30. The organic photoelectric conversion section 20 is coupled, through this through electrode 34, to a gate Gamp of the amplifier transistor AMP provided on the second surface 30B side of the semiconductor substrate 30 and the one source/drain region 36B of the reset transistor RST (reset transistor Tr1rst) also serving as the floating diffusion FD1. This allows the imaging element 10 to favorably transfer the electric charge (electrons here) generated by the organic photoelectric conversion section 20 on the first surface 30A side of the semiconductor substrate 30 to the second surface 30B side of the semiconductor substrate 30 through the through electrode 34 and increase the characteristics.

The lower end of the through electrode 34 is coupled to a coupling section 41A in the wiring layer 41 and the coupling section 41A and the gate Gamp of the amplifier transistor AMP are coupled through a lower first contact 45. The coupling section 41A and the floating diffusion FD1 (region 36B) are coupled, for example, through a lower second contact 46. The upper end of the through electrode 34 is coupled to the readout electrode 21A, for example, through a pad section 39A and an upper first contact 39C.

The through electrode 34 is provided, for example, for each of the organic photoelectric conversion sections 20 in the respective imaging elements 10. The through electrode 34 has a function of a connector for the organic photoelectric conversion section 20 and the gate Gamp of the amplifier transistor AMP and the floating diffusion FD1 and serves as a transmission path for the electric charge generated by the organic photoelectric conversion section 20.

A reset gate Grst of the reset transistor RST is disposed next to the floating diffusion FD1 (the one source/drain region 36B of the reset transistor RST). This allows the reset transistor RST to reset the electric charge accumulated in the floating diffusion FD1.

In the imaging element 10 according to the present embodiment, light having entered the organic photoelectric conversion section 20 from the upper electrode 27 side is absorbed by the photoelectric conversion layer 24. The excitons generated by this move to the interface between an electron donor and an electron acceptor included in the photoelectric conversion layer 24 and undergo exciton separation. In other words, the excitons are dissociated into electrons and holes. The electric charge (electrons and holes) generated here is transported to different electrodes by diffusion due to a carrier concentration difference and an internal electric field caused by a work function difference between the anode (upper electrode 27 here) and the cathode (lower electrode 21 here). The transported electric charge is detected as a photocurrent. In addition, the application of a potential between the lower electrode 21 and the upper electrode 27 makes it possible to control the transport directions of electrons and holes.

The following describes configurations, materials, and the like of the respective sections.

The organic photoelectric conversion section 20 is an organic photoelectric conversion element that absorbs green light corresponding to a selective wavelength range including, for example, a portion or the whole of a wavelength range of 450 nm or more and 650 nm or less and generates excitons.

As described above, the lower electrode 21 includes the readout electrode 21A and the accumulation electrode 21B that are separately formed. The readout electrode 21A is for transferring the electric charge (electrons here) generated in the organic photoelectric conversion layer 24 to the floating diffusion FD1. The readout electrode 21A is coupled to the floating diffusion FD1, for example, through the upper first contact 39C, the pad section 39A, the through electrode 34, the coupling section 41A, and the lower second contact 46. The accumulation electrode 21B is for accumulating the electrons of the electric charge generated in the photoelectric conversion layer 24 in the electric charge accumulation layer 23 as signal charge. The accumulation electrode 21B is provided in a region that is opposed to the light receiving surfaces of the inorganic photoelectric conversion sections 32B and 32R formed in the semiconductor substrate 30 and covers these light receiving surfaces. It is preferable that the accumulation electrode 21B be larger than the readout electrode 21A. This makes it possible to accumulate more electric charge.

The lower electrode 21 includes an electrically conducive film having light transmissivity. The lower electrode 21 includes, for example, ITO (indium tin oxide). However, in addition to this ITO, a tin oxide (SnO₂)-based material to which a dopant is added or a zinc oxide-based material obtained by adding a dopant to zinc oxide (ZnO) may be used as a material included in the lower electrode 21. Examples of the zinc oxide-based material include aluminum zinc oxide (AZO) to which aluminum (Al) is added as a dopant, gallium zinc oxide (GZO) to which gallium (Ga) is added, and indium zinc oxide (IZO) to which indium (In) is added. In addition, CuI, InSbO₄, ZnMgO, CuInO₂, MglN₂O₄, CdO, ZnSnO₃, or the like may also be used in addition to these.

The electric charge accumulation layer 23 is provided in a lower layer of the photoelectric conversion layer 24. Specifically, the electric charge accumulation layer 23 is provided between the insulating layer 22 and the photoelectric conversion layer 24. The electric charge accumulation layer 23 is for accumulating the signal charge generated in the photoelectric conversion layer 24. In the present embodiment, electrons are used as signal charge. It is therefore preferable that the electric charge accumulation layer 23 be formed by using an n-type semiconductor material. For example, it is preferable to use a material having, at the lowest edge of the conduction band, a shallower energy level than the work function of the lower electrode 21. Examples of such an n-type semiconductor material include IGZO (In—Ga—Zn—O-based oxide semiconductor), ZTO (Zn—Sn—O-based oxide semiconductor), IGZTO (In—Ga—Zn—Sn—O-based oxide semiconductor), GTO (Ga—Sn—O-based oxide semiconductor), IGO (In—Ga—O-based oxide semiconductor), and the like. It is preferable to use at least one of the oxide semiconductor materials described above for the electric charge accumulation layer 23. Among them, IGZO is favorably used. The electric charge accumulation layer 23 has, for example, a thickness of 30 nm or more and 200 nm or less. The electric charge accumulation layer 23 preferably has a thickness of 60 nm or more and 150 nm or less. Providing the electric charge accumulation layer 23 including the materials described above in a lower layer of the photoelectric conversion layer 24 makes it possible to prevent electric charge from being recombined during electric charge accumulation and increase the transfer efficiency.

The photoelectric conversion layer 24 is for converting light energy to electric energy. The photoelectric conversion layer 24 includes, for example, two or more types of organic semiconductor materials (p-type semiconductor material or n-type semiconductor material) that each function as a p-type semiconductor or an n-type semiconductor. The photoelectric conversion layer 24 has, in the layer, the junction surface (p/n junction surface) between these p-type semiconductor material and n-type semiconductor material. The p-type semiconductor relatively functions as an electron donor (donor) and the n-type semiconductor relatively functions as an electron acceptor (acceptor). The photoelectric conversion layer 24 provides a field in which excitons generated in absorbing light are separated into electrons and holes. Specifically, excitons are separated into electrons and holes at the interface (p/n junction surface) between the electron donor and the electron acceptor.

The photoelectric conversion layer 24 may include an organic material or a so-called dye material in addition to the p-type semiconductor material and the n-type semiconductor material. The organic material or the dye material photoelectrically converts light in a predetermined wavelength range and transmits light in another wavelength range. In a case where the photoelectric conversion layer 24 is formed by using the three types of organic materials including a p-type semiconductor material, an n-type semiconductor material, and a dye material, it is preferable that the p-type semiconductor material and the n-type semiconductor material be materials each having light transmissivity in a visible region (e.g., 450 nm or more and 800 nm or less). The photoelectric conversion layer 24 has, for example, a thickness of 50 nm or more and 500 nm or less.

It is preferable that the photoelectric conversion layer 24 according to the present embodiment include an organic material and have absorption between the visible light and the near-infrared light. Examples of an organic material included in the photoelectric conversion layer 24 include quinacridone, boron chloride subphthalocyanine, pentacene, benzothienobenzothiophene, fullerene, and derivatives thereof. The photoelectric conversion layer 24 includes two or more of the organic materials described above in combination. The organic materials described above function as a p-type semiconductor or an n-type semiconductor depending on the combination.

It is to be noted that the organic materials included in the photoelectric conversion layer 24 are not limited in particular. For example, any one of naphthalene, anthracene, phenantherene, tetracene, pyrene, perylene, and fluoranthene or derivatives thereof is favorably used in addition to the organic materials described above. Alternatively, a polymer such as phenylenevinylene, fluorene, carbazole, indole, pyrene, pyrrole, picoline, thiophene, acetylene, or diacetylene or a derivative thereof may be used. Additionally, it is possible to favorably use a metal complex dye, a cyanine-based dye, a merocyanine-based dye, a phenylxanthene-based dye, a triphenylmethane-based dye, a rhodacyanine-based dye, a xanthene-based dye, a macrocyclic azaannulene-based dye, an azulene-based dye, naphthoquinone, an anthraquinone-based dye, a chain compound in which a fused polycyclic aromatic group such as anthracene and pyrene and an aromatic ring or a heterocyclic compound are fused, a cyanine-like dye bonded by two nitrogen-containing hetero rings such as quinoline, benzothiazole, and benzoxazole that have a squarylium group and a croconic methine group as a bonded chain or by a squarylium group and a croconic methine group, or the like. It is to be noted that a dithiol metal complex-based dye, a metallophthalocyanine dye, a metalloporphyrine dye, or a ruthenium complex dye is preferable as the metal complex dye described above, but this is not limitative.

The work function adjustment layer 25 is provided in an upper layer of the photoelectric conversion layer 24. The work function adjustment layer 25 is for changing an internal electric field in the photoelectric conversion layer 24 to rapidly transfer and accumulate the signal charge generated by the photoelectric conversion layer 24 to and in the electric charge accumulation layer 23. The work function adjustment layer 25 has light transmissivity. It is preferable that the work function adjustment layer 25 have, for example, a light absorptivity of 10% or less for visible light. In addition, it is possible to form the work function adjustment layer 25 by using a carbon-containing compound having a greater electron affinity than the work function of the electric charge accumulation layer 23. It is to be noted that the electron affinity corresponds to the difference between the LUMO level (LUMO2) and the vacuum level calculated from the optical band gap described below.

Examples of a material included in the work function adjustment layer 25 include tetracyanoquinodimethane derivatives such as 2,3,5,6-tetrafluoro-tetracyanoquinodimethane (F4-TCNQ), 2,3,5-trifluoro-tetracyanoquinodimethane (F3-TCNQ), 2,5-difluoro-tetracyanoquinodimethane (F2-TCNQ), 2-fluoro-tetracyanoquinodimethane (F1-TCNQ), 2-trifluoromethyl-tetracyanoquinodimethane (CF3-TCNQ), and 1,3,4,5,7,8-hexafluoro-tetracyanonaphthoquinodimethane (F6-TCNQ), a hexaazatriphenylene derivative such as 1,4,5,8,9,12-hexaazatriphenylene-2,3,6,7,10,11-hexacarbonitrile (HATCN), hexaazatrinaphthylene derivatives such as 2,3,8,9,14,15-hexachloro-5,6,11,12,17,18-hexaazatrinaphthylene (HATNA-Cl6) and 2,3,8,9,14,15-hexafluoro-5,6,11,12,17,18-hexaazatrinaphthylene (HATNA-F6), a phthalocyanine derivative such as 1,2,3,4,8,9,10,11,15,16,17,18,22,23,24,25-hexadecafluoro-copper phthalocyanine (F16-CuPc), fluorinated fullerenes such as C₆₀F₃₆ and C₆₀F₄₈, and the like. Alternatively, it is possible to form the work function adjustment layer 25 by using an inorganic compound having a greater work function than the work function of the lower electrode 21 (the accumulation electrode 21B in particular). Examples of such a material include transition metal oxides such as molybdenum oxide (MoO₃), tungsten oxide (WO₃), vanadium oxide (V₂O₅), and rhenium oxide (ReO₃), salts such as copper iodide (CuI), antimony chloride (SbCl₅), iron oxide (FeCl₃), and sodium chloride (NaCl), and the like. The work function adjustment layer 25 may be formed as a single layer film for which the carbon-containing compound or the inorganic compound described above is used alone, but may also be formed as a stacked film of a layer including a carbon compound and a layer including an inorganic compound. In that case, it is preferable to stack a carbon-containing compound film and an inorganic compound film in this order in consideration of damage caused by annealing treatment for the film formation of the upper electrode 27. The work function adjustment layer 25 has, for example, a thickness of 0.5 nm or more and 30 nm or less.

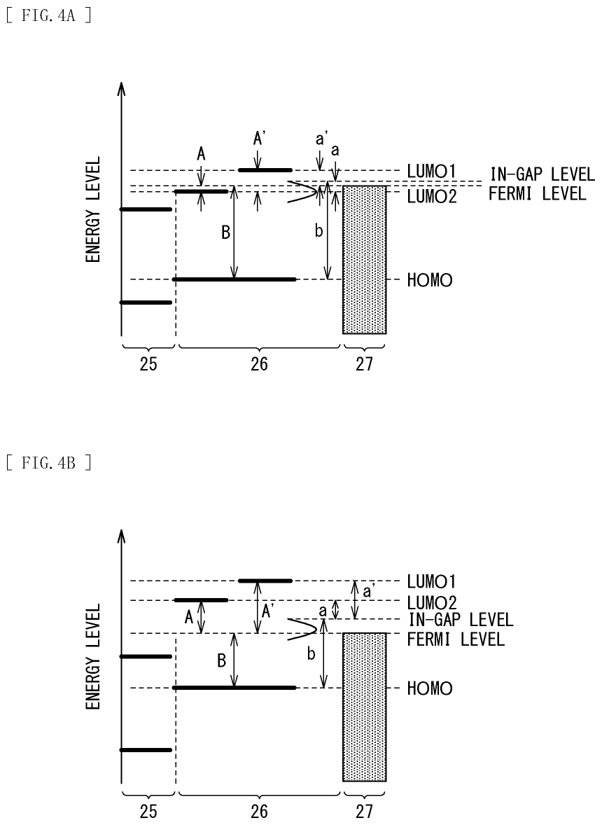

The electron injection promoting layer 26 is provided between the work function adjustment layer 25 and the upper electrode 27 and promotes electrons to be injected from the upper electrode 27. As in the present embodiment, in the imaging element 10 that reads out electrons from the readout electrode 21A as signal charge, the holes generated by the photoelectric conversion layer 24 are recombined with the electrons injected from the upper electrode 27 at the interface between the work function adjustment layer 25 and the organic layer including the photoelectric conversion layer 24 adjacent to the work function adjustment layer 25. This recombination causes electrons (signal charge) to be efficiently read out from the readout electrode 21A. The recombination of holes and electrons at the interface between the work function adjustment layer 25 and the organic layer including the photoelectric conversion layer 24 adjacent to the work function adjustment layer 25 depends on the charge density of holes and electrons. The injection of electrons from the upper electrode 27 to the work function adjustment layer 25 is promoted by the electron injection promoting layer 26 having an energy level, for example, as illustrated in FIG. 4A or 4B.

For example, it is preferable for the electron injection promoting layer 26 that an absolute value B of the difference between the HOMO (Highest Occupied Molecular Orbital) level and the Fermi level of the upper electrode 27 be greater than or equal to an absolute value A of the difference between the LUMO (Lowest Unoccupied Molecular Orbital) level (corresponding to LUMO2 or a first LUMO level) calculated from the optical band gap and the Fermi level of the upper electrode 27 (1). Specifically, for example, it is preferable that the absolute value B of the difference between the HOMO level and the Fermi level of the upper electrode 27 be 1.5 or more times as great as the absolute value A of the difference between LUMO2 and the Fermi level of the upper electrode 27. Further, it is preferable for the electron injection promoting layer 26 that the absolute value B of the difference between the HOMO level and the Fermi level of the upper electrode 27 be greater than an absolute value A′ of the difference between the LUMO level (LUMO1) and the Fermi level of the upper electrode 27 (2).

Alternatively, it is preferable that the electron injection promoting layer 26 have an in-gap level having a state density of 1/10000 or more as compared with the HOMO level near the Fermi level of the upper electrode 27 (3). More specifically, for example, it is preferable that an absolute value b of the difference between the HOMO level and the in-gap level of the electron injection promoting layer 26 be two or more times as great as an absolute value a of the difference between the LUMO level (LUMO2) calculated from the optical band gap and the in-gap level (4). Alternatively, it is preferable that the absolute value b of the difference between the HOMO level and the in-gap level of the electron injection promoting layer 26 be 1.5 or more times as great as an absolute value a′ of the difference between the LUMO level (LUMO1) and the in-gap level (5).

It is to be noted that the HOMO level and the LUMO level (LUMO2) described above are respectively obtained by using ultraviolet photoelectron spectroscopy (Ultraviolet Photoelectron Spectroscopy: UPS) and ultraviolet-visible spectroscopy. The LUMO level (LUMO1) is obtained by using low-energy inverse photoemission spectroscopy (Low-Energy Inverse Photoemission Spectroscopy: LEIPS). The difference between LUMO1 and LUMO2 corresponds to exciton binding energy.

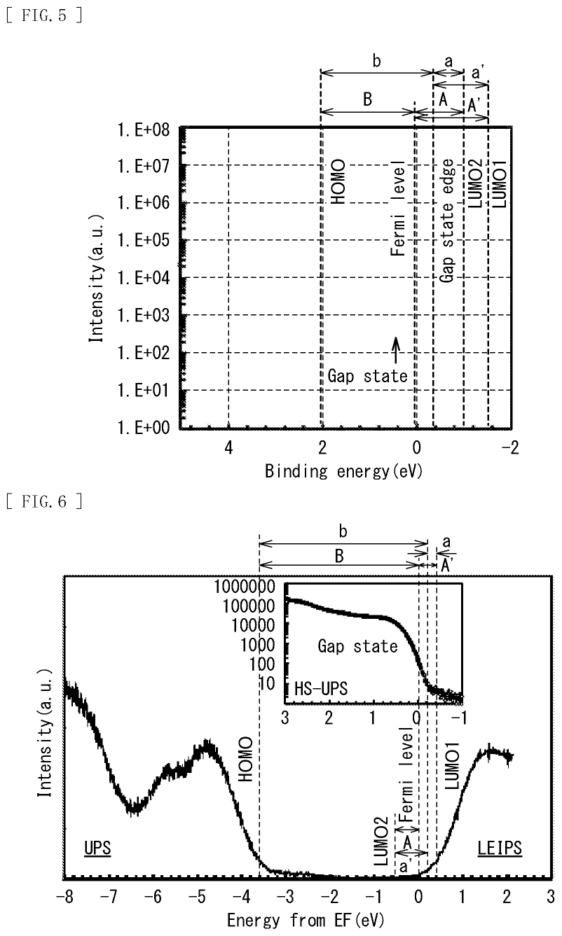

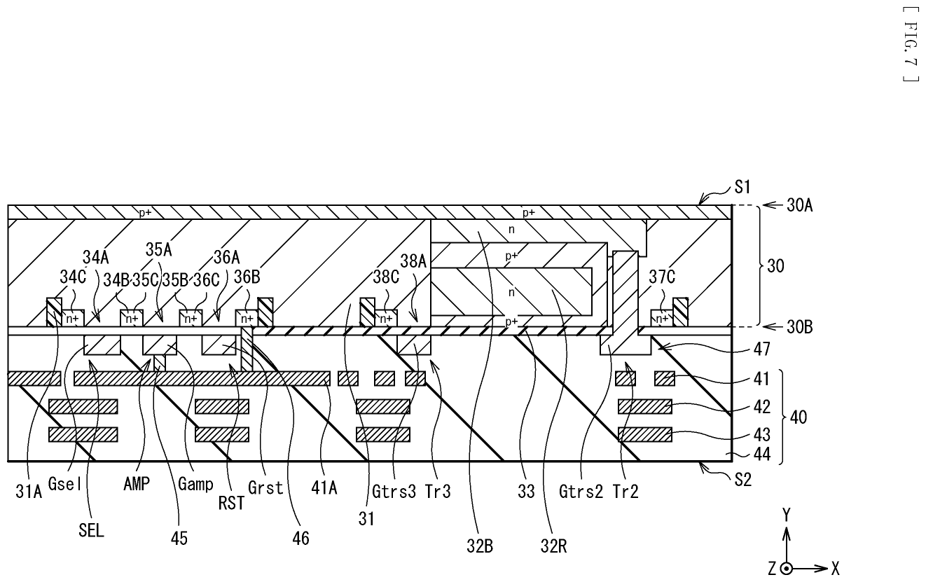

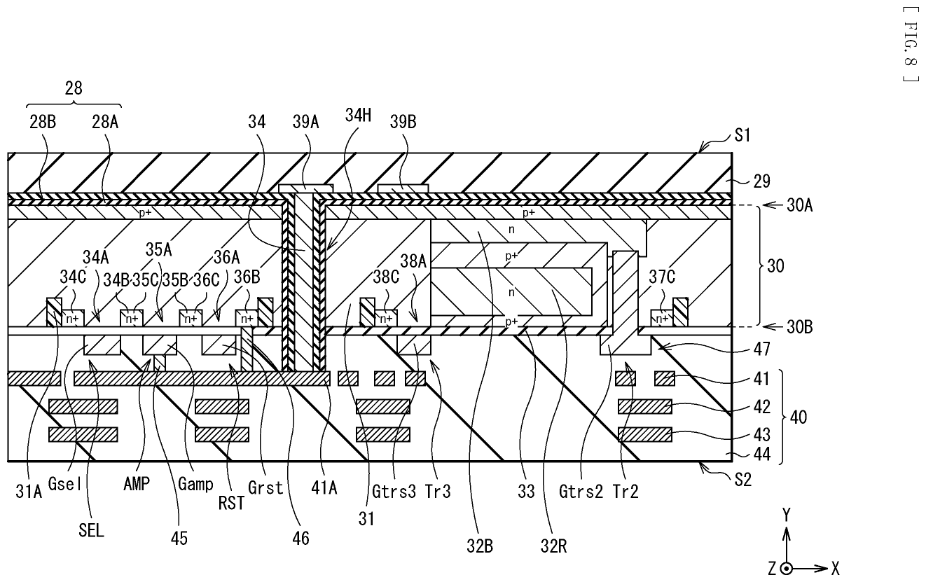

Examples of materials included in the electron injection promoting layer 26 include [2,9-bis(naphthalen-2-yl)-4,7-diphenyl-1,10-phenanthroline] (NBphen), a naphthalene diimide-based molecule (e.g., NDI35), and lithium fluoride (LiF). FIG. 5 illustrates that the respective energy levels of NBphen are analyzed by high-sensitivity ultraviolet photoemission spectroscopy (high-sensitivity Ultraviolet photoemission spectroscopy: HS-UPS). NBphen satisfies (1), (3), and (4) described above. In addition, even in a case where the exciton binding energy is taken into consideration, (1), (2), and (5) described above are satisfied. FIG. 6 illustrates that the respective energy levels of NDI35 are analyzed by UPS and low-energy inverse photoemission spectroscopy (LEIPS). NDI35 satisfies all of (1) to (5) described above. The electron injection promoting layer 26 has, for example, a thickness of 0.5 nm or more and 10 nm or less.

There may be provided other organic layers between the photoelectric conversion layer 24 and the lower electrode 21 (e.g., between the electric charge accumulation layer 23 and the photoelectric conversion layer 24) and between the photoelectric conversion layer 24 and the upper electrode 27 (e.g., between the photoelectric conversion layer 24 and the work function adjustment layer 25). Specifically, for example, the electric charge accumulation layer 23, a hole blocking layer, the photoelectric conversion layer 24, an electron blocking layer, the work function adjustment layer 25, the electron injection promoting layer 26, and the like may be stacked in order from the lower electrode 21 side. Further, there may be provided an underlying layer and a hole transport layer between the lower electrode 21 and the photoelectric conversion layer 24 and there may be provided a buffer layer and the like between the photoelectric conversion layer 24 and the upper electrode 27. It is to be noted that, in a case where there is provided a buffer layer between the photoelectric conversion layer 24 and the upper electrode 27, for example, to be adjacent to the electron injection promoting layer 26, the buffer layer preferably has a shallower energy level than the work function of the work function adjustment layer 25. In addition, it is preferable that the buffer layer be formed by using an organic material having, for example, a glass transition point of more than 100° C.

The upper electrode 27 includes an electrically conducive film having light transmissivity as with the lower electrode 21. In the imaging device 1 in which the imaging element 10 is used as one pixel, the upper electrodes 27 may be separated for each of the pixels or the upper electrode 27 may be formed as an electrode common to the respective pixels. The upper electrode 27 has, for example, a work function smaller than the work function of the work function adjustment layer 25. The upper electrode 27 has, for example, a thickness of 10 nm to 200 nm.

The fixed electric charge layer 28A may be a film having positive fixed electric charge or a film having negative fixed electric charge. As a material of the film having negative fixed electric charge, hafnium oxide, aluminum oxide, zirconium oxide, tantalum oxide, titanium oxide, and the like are included. In addition, as a material other than the materials described above, lanthanum oxide, praseodymium oxide, cerium oxide, neodymium oxide, promethium oxide, samarium oxide, europium oxide, gadolinium oxide, terbium oxide, dysprosium oxide, holmium oxide, thulium oxide, ytterbium oxide, lutetium oxide, yttrium oxide, an aluminum nitride film, a hafnium oxynitride film, an aluminum oxynitride film, or the like is included.

The fixed electric charge layer 28A may also have a configuration in which two or more types of films are stacked. This makes it possible to further increase a function of a hole accumulation layer in a case of a film having, for example, negative fixed electric charge.

Although a material of the dielectric layer 28B is not limited in particular, the dielectric layer 28B is formed by using, for example, a silicon oxide film, TEOS, a silicon nitride film, a silicon oxynitride film, or the like.

The interlayer insulating layer 29 includes, for example, a single layer film including one of silicon oxide, silicon nitride, silicon oxynitride (SiON), and the like or a stacked film including two or more of them.

The insulating layer 22 is for electrically separating the accumulation electrode 21B and the electric charge accumulation layer 23. The insulating layer 22 is provided, for example, above the interlayer insulating layer 29 to cover the lower electrode 21. The insulating layer 22 is provided with the opening 22H above the readout electrode 21A as described above and the readout electrode 21A and the electric charge accumulation layer 23 are electrically coupled through this opening 22H. It is possible to form the insulating layer 22 by using, for example, a material similar to that of the interlayer insulating layer 29. The insulating layer 22 includes, for example, a single layer film including one of silicon oxide, silicon nitride, silicon oxynitride (SiON), and the like or a stacked film including two or more of them. The insulating layer 22 has, for example, a thickness of 20 nm to 500 nm.

The semiconductor substrate 30 includes, for example, an n-type silicon (Si) substrate and includes a p-well 31 in a predetermined region. The transfer transistors Tr2 and Tr3, the amplifier transistor AMP, the reset transistor RST, the selection transistor SEL, and the like described above are provided on the second surface 30B of the p-well 31. In addition, a peripheral portion of the semiconductor substrate 30 is provided with a peripheral circuit portion 130 (see, for example, FIG. 15) including a logic circuit or the like.

The reset transistor RST (reset transistor Tr1rst) resets the electric charge transferred from the organic photoelectric conversion section 20 to the floating diffusion FD1 and includes, for example, a MOS transistor. Specifically, the reset transistor Tr1rst includes the reset gate Grst, a channel formation region 36A, and the source/drain regions 36B and 36C. The reset gate Grst is coupled to a reset line RST1. The one source/drain region 36B of the reset transistor Tr1rst also serves as the floating diffusion FD1. The other source/drain region 36C included in the reset transistor Tr1rst is coupled to a power supply line VDD.

The amplifier transistor AMP is a modulation element that modulates, to a voltage, the amount of electric charge generated by the organic photoelectric conversion section 20 and includes, for example, a MOS transistor. Specifically, the amplifier transistor AMP includes the gate Gamp, a channel formation region 35A, and the source/drain regions 35B and 35C. The gate Gamp is coupled to the readout electrode 21A and the one source/drain region 36B (floating diffusion FD1) of the reset transistor Tr1rst through the lower first contact 45, the coupling section 41A, the lower second contact 46, the through electrode 34, and the like. In addition, the one source/drain region 35B shares a region with the other source/drain region 36C included in the reset transistor Tr1rst and is coupled to the power supply line VDD.

The selection transistor SEL (selection transistor TR1sel) includes a gate Gsel, a channel formation region 34A, and source/drain regions 34B and 34C. The gate Gsel is coupled to a selection line SELL In addition, the one source/drain region 34B shares a region with the other source/drain region 35C included in the amplifier transistor AMP and the other source/drain region 34C is coupled to a signal line (data output line) VSL1.

Each of the inorganic photoelectric conversion sections 32B and 32R has a pn junction in a predetermined region of the semiconductor substrate 30. The inorganic photoelectric conversion sections 32B and 32R each allow light to be dispersed in the vertical direction because pieces of light to be absorbed have different wavelengths in accordance with the light incidence depth in a silicon substrate. The inorganic photoelectric conversion section 32B selectively detects, for example, blue light to accumulate the signal charge corresponding to blue. The inorganic photoelectric conversion section 32B is installed at a depth that allows the blue light to be photoelectrically converted efficiently. The inorganic photoelectric conversion section 32R selectively detects, for example, red light to accumulate the signal charge corresponding to red. The inorganic photoelectric conversion section 32R is installed at a depth that allows the red light to be photoelectrically converted efficiently. It is to be noted that blue (B) is a color corresponding, for example, to a wavelength range of 450 nm to 495 nm and red (R) is a color corresponding, for example, to a wavelength range of 620 nm to 750 nm. It is sufficient if each of the inorganic photoelectric conversion sections 32B and 32R is configured to detect light in a portion or the whole of the wavelength range.

The inorganic photoelectric conversion section 32B includes, for example, a p+ region serving as a hole accumulation layer and an n region serving as an electron accumulation layer. The inorganic photoelectric conversion section 32R includes, for example, a p+ region serving as a hole accumulation layer and an n region serving as an electron accumulation layer (has a p-n-p stacked structure). The n region of the inorganic photoelectric conversion section 32B is coupled to the vertical transfer transistor Tr2. The p+ region of the inorganic photoelectric conversion section 32B is bent along the transfer transistor Tr2 and leads to the p+ region of the inorganic photoelectric conversion section 32R.

The transfer transistor Tr2 (transfer transistor TR2trs) is for transferring, to the floating diffusion FD2, the signal charge (electrons here) corresponding to blue that has been generated and accumulated in the inorganic photoelectric conversion section 32B. The inorganic photoelectric conversion section 32B is formed at a deep position from the second surface 30B of the semiconductor substrate 30 and it is thus preferable that the transfer transistor TR2trs of the inorganic photoelectric conversion section 32B include a vertical transistor. In addition, the transfer transistor TR2trs is coupled to a transfer gate line TG2. Further, the floating diffusion FD2 is provided in the region 37C near a gate Gtrs2 of the transfer transistor TR2trs. The electric charge accumulated in the inorganic photoelectric conversion section 32B is read out to the floating diffusion FD2 through a transfer channel formed along the gate Gtrs2.

The transfer transistor Tr3 (transfer transistor TR3trs) transfers, to the floating diffusion FD3, the signal charge (electrons here) corresponding to red that has been generated and accumulated in the inorganic photoelectric conversion section 32R. The transfer transistor Tr3 (transfer transistor TR3trs) includes, for example, a MOS transistor. In addition, the transfer transistor TR3trs is coupled to a transfer gate line TG3. Further, the floating diffusion FD3 is provided in the region 38C near a gate Gtrs3 of the transfer transistor TR3trs. The electric charge accumulated in the inorganic photoelectric conversion section 32R is read out to the floating diffusion FD3 through a transfer channel formed along the gate Gtrs3.

The second surface 30B side of the semiconductor substrate 30 is further provided with a reset transistor TR2rst, an amplifier transistor TR2amp, and a selection transistor TR2sel included in the controller of the inorganic photoelectric conversion section 32B. In addition, there are provided a reset transistor TR3rst, an amplifier transistor TR3amp, and a selection transistor TR3sel included in the controller of the inorganic photoelectric conversion section 32R.

The reset transistor TR2rst includes a gate, a channel formation region, and source/drain regions. The gate of the reset transistor TR2rst is coupled to a reset line RST2 and the one source/drain region of the reset transistor TR2rst is coupled to the power supply line VDD. The other source/drain region of the reset transistor TR2rst also serves as the floating diffusion FD2.

The amplifier transistor TR2amp includes a gate, a channel formation region, and source/drain regions. The gate is coupled to the other source/drain region (floating diffusion FD2) of the reset transistor TR2rst. In addition, the one source/drain region included in the amplifier transistor TR2amp shares a region with the one source/drain region included in the reset transistor TR2rst and is coupled to the power supply line VDD.

The selection transistor TR2sel includes a gate, a channel formation region, and source/drain regions. The gate is coupled to a selection line SEL2. In addition, the one source/drain region included in the selection transistor TR2sel shares a region with the other source/drain region included in the amplifier transistor TR2amp. The other source/drain region included in the selection transistor TR2sel is coupled to a signal line (data output line) VSL2.

The reset transistor TR3rst includes a gate, a channel formation region, and source/drain regions. The gate of the reset transistor TR3rst is coupled to a reset line RST3 and the one source/drain region included in the reset transistor TR3rst is coupled to the power supply line VDD. The other source/drain region included in the reset transistor TR3rst also serves as the floating diffusion FD3.

The amplifier transistor TR3amp includes a gate, a channel formation region, and source/drain regions. The gate is coupled to the other source/drain region (floating diffusion FD3) included in the reset transistor TR3rst. In addition, the one source/drain region included in the amplifier transistor TR3amp shares a region with the one source/drain region included in the reset transistor TR3rst and is coupled to the power supply line VDD.

The selection transistor TR3sel includes a gate, a channel formation region, and source/drain regions. The gate is coupled to a selection line SEL3. In addition, the one source/drain region included in the selection transistor TR3sel shares a region with the other source/drain region included in the amplifier transistor TR3amp. The other source/drain region included in the selection transistor TR3sel is coupled to a signal line (data output line) VSL3.

The reset lines RST1, RST2, and RST3, the selection lines SEL1, SEL2, and SEL3, and the transfer gate lines TG2 and TG3 are each coupled to a vertical drive circuit 112 included in a drive circuit. The signal lines (data output lines) VSL1, VSL2, and VSL3 are coupled to a column signal processing circuit 113 included in the drive circuit.

The lower first contact 45, the lower second contact 46, the upper first contact 39C, and an upper second contact 39D each include, for example, a doped silicon material such as PDAS (Phosphorus Doped Amorphous Silicon) or a metal material such as aluminum (Al), tungsten (W), titanium (Ti), cobalt (Co), hafnium (Hf), or tantalum (Ta).

The protective layer 51 is provided above the organic photoelectric conversion section 20 and includes a material having light transmissivity. Specifically, the protective layer 51 includes, for example, a single layer film including any of silicon oxide, silicon nitride, silicon oxynitride, and the like or a stacked film including two or more of them. This protective layer 51 has, for example, a thickness of 100 nm to 30000 nm.

The light shielding film 52 is provided in the protective layer 51, for example, to cover the readout electrode 21A. Examples of a material of the light shielding film 52 include tungsten (W), titanium (Ti), titanium nitride (TiN), or aluminum (Al). The light shielding film 52 is configured, for example, as a stacked film of W/TiN/Ti or a single layer film of W. The light shielding film 52 has, for example, a thickness of 50 nm or more and 400 nm or less.

A pixel section 1a on the protective layer 51 is provided, for example, with the on-chip lens 53 for each of the unit pixels P. The on-chip lens 53 condenses incident light on the respective light receiving surfaces of the organic photoelectric conversion section 20, the inorganic photoelectric conversion section 32B, and the inorganic photoelectric conversion section 32R.

### 1-2. Method of Manufacturing Imaging Element

It is possible to manufacture the imaging element 10 according to the present embodiment, for example, as follows.

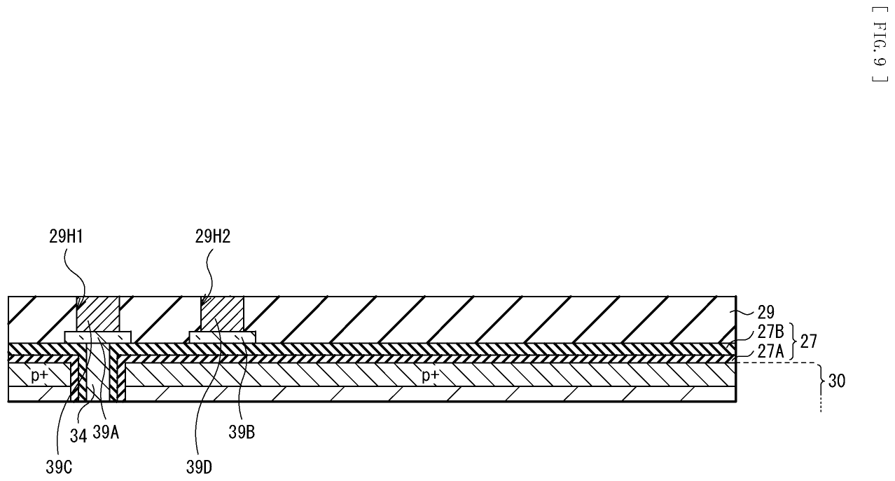

FIGS. 7 to 13 illustrate a method of manufacturing the imaging element 10 in the order of steps. First, as illustrated in FIG. 7, for example, the p-well 31 is formed in the semiconductor substrate 30 as a well of a first electrical conduction type. The inorganic photoelectric conversion sections 32B and 32R of a second electrical conduction type (e.g., n type) are formed in this p-well 31. A p+ region is formed near the first surface 30A of the semiconductor substrate 30.

As also illustrated in FIG. 7, for example, n+ regions that serve as the floating diffusions FD1 to FD3 are formed on the second surface 30B of the semiconductor substrate 30 and a gate insulating layer 33 and a gate wiring layer 47 are then formed. The gate wiring layer 47 includes the respective gates of the transfer transistor Tr2, the transfer transistor Tr3, the selection transistor SEL, the amplifier transistor AMP, and the reset transistor RST. This forms the transfer transistor Tr2, the transfer transistor Tr3, the selection transistor SEL, the amplifier transistor AMP, and the reset transistor RST. Further, the multilayer wiring layer 40 is formed on the second surface 30B of the semiconductor substrate 30. The multilayer wiring layer 40 includes the wiring layers 41 to 43 and the insulating layer 44. The wiring layers 41 to 43 include the lower first contact 45, the lower second contact 46, and the coupling section 41A.

As the base of the semiconductor substrate 30, for example, an SOI (Silicon on Insulator) substrate is used in which the semiconductor substrate 30, a buried oxide film (not illustrated), and a holding substrate (not illustrated) are stacked. Although not illustrated in FIG. 7, the buried oxide film and the holding substrate are joined to the first surface 30A of the semiconductor substrate 30. After ion implantation, annealing treatment is performed.

Next, a support substrate (not illustrated), another semiconductor base, or the like is joined to the second surface 30B side (multilayer wiring layer 40 side) of the semiconductor substrate 30 and flipped vertically. Subsequently, the semiconductor substrate 30 is separated from the buried oxide film and the holding substrate of the SOI substrate to expose the first surface 30A of the semiconductor substrate 30. It is possible to perform the steps described above with technology used in a normal CMOS process such as ion implantation and CVD (Chemical Vapor Deposition).

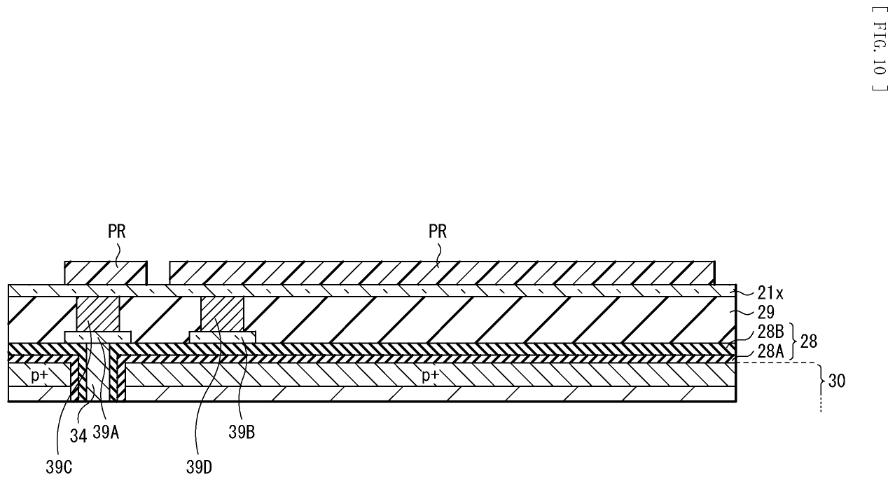

Next, as illustrated in FIG. 8, the semiconductor substrate 30 is processed from the first surface 30A side, for example, by dry etching to form, for example, an annular opening 34H. The depth of the opening 34H extends from the first surface 30A to the second surface 30B of the semiconductor substrate 30 and reaches, for example, the coupling section 41A as illustrated in FIG. 8.

Subsequently, for example, the negative fixed electric charge layer 28A is formed on the first surface 30A of the semiconductor substrate 30 and the side surface of the opening 34H. Two or more types of films may be stacked as the negative fixed electric charge layer 28A. This makes it possible to further increase a function of a hole accumulation layer. The dielectric layer 28B is formed after the negative fixed electric charge layer 28A is formed. Next, the pad sections 39A and 39B are formed at predetermined positions on the dielectric layer 28B. After that, the interlayer insulating layer 29 is formed on the dielectric layer 28B and the pad sections 39A and 39B and the surface of the interlayer insulating layer 29 is planarized by using a CMP (Chemical Mechanical Polishing) method.

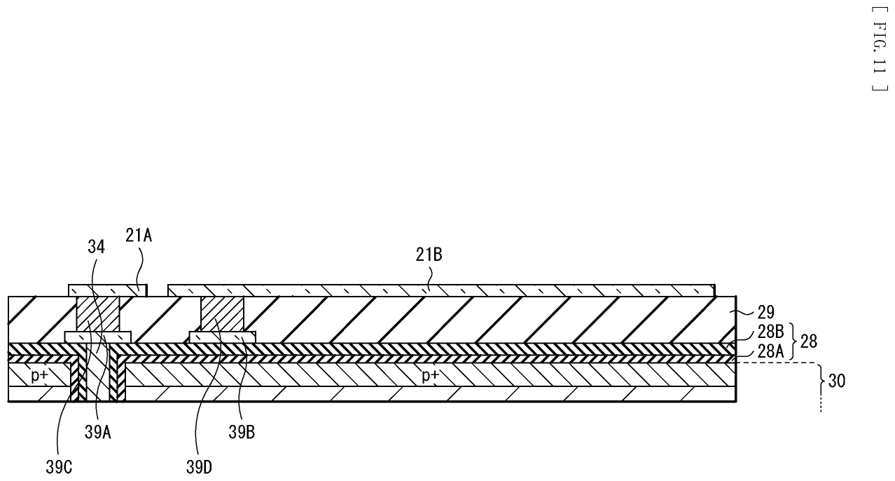

Subsequently, as illustrated in FIG. 9, openings 29H1 and 29H2 are respectively formed above the pad sections 39A and 39B. After that, these openings 29H1 and 29H2 are filled, for example, with electrically conductive materials such as Al to form the upper first contact 39C and the upper second contact 39D.

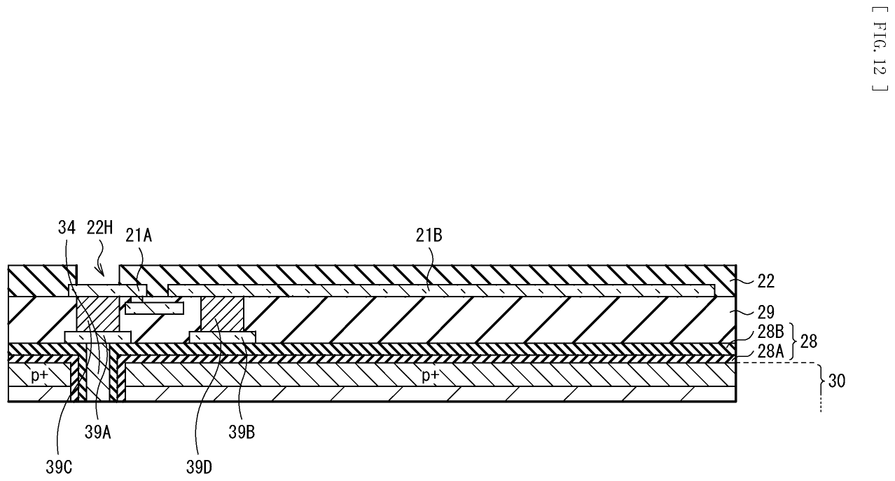

Next, as illustrated in FIG. 10, an electrically conducive film 21x is formed on the interlayer insulating layer 29. After that, a photoresist PR is formed at a predetermined position on the electrically conducive film 21x. After that, the readout electrode 21A and the accumulation electrode 21B illustrated in FIG. 11 are patterned by etching and removing the photoresist PR.

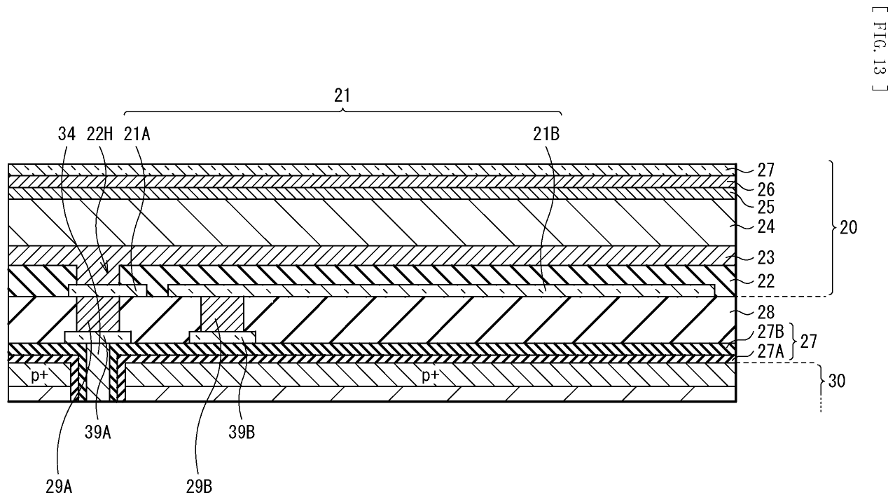

Subsequently, as illustrated in FIG. 12, the insulating layer 22 is formed on the interlayer insulating layer 29 and the readout electrode 21A and the accumulation electrode 21B. After that, the opening 22H is provided above the readout electrode 21A.

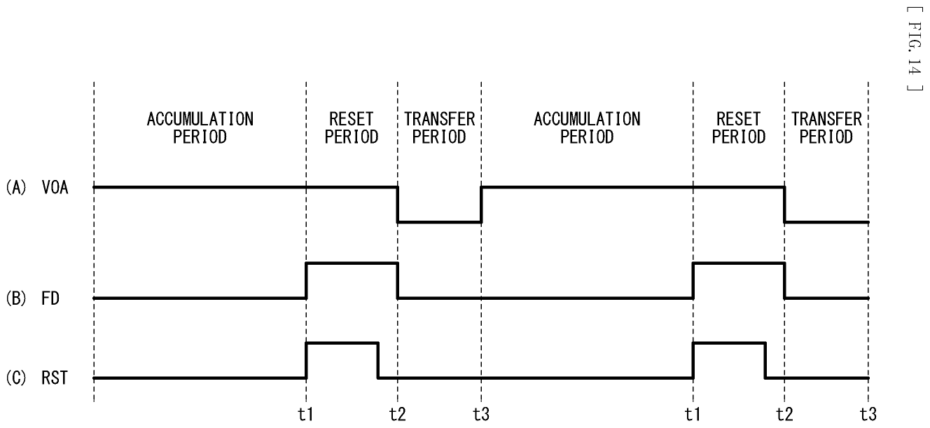

Next, as illustrated in FIG. 13, the electric charge accumulation layer 23, the photoelectric conversion layer 24, the work function adjustment layer 25, the electron injection promoting layer 26, and the upper electrode 27 are formed on the insulating layer 22. It is to be noted that, in a case where the electric charge accumulation layer 23, the work function adjustment layer 25, and the electron injection promoting layer 26 are formed by using organic materials, it is desirable to continuously form the electric charge accumulation layer 23, the photoelectric conversion layer 24, and the work function adjustment layer 25 in a vacuum process (in-situ vacuum process). In addition, the method of forming the photoelectric conversion layer 24 is not necessarily limited to a technique that uses a vacuum evaporation method. Another method may be used such as spin coating technology or printing technology, for example. Finally, the protective layer 51 including the light shielding film 52 and the on-chip lens 53 are formed above the organic photoelectric conversion section 20. Thus, the imaging element 10 illustrated in FIG. 1 is completed.

In a case where light enters the organic photoelectric conversion section 20 through the on-chip lens 53 in the imaging element 10, the light passes through the organic photoelectric conversion section 20 and the inorganic photoelectric conversion sections 32B and 32R in this order. While the light passes through the organic photoelectric conversion section 20 and the inorganic photoelectric conversion sections 32B and 32R, the light is photoelectrically converted for each of green light, blue light, and red light. The following describes operations of acquiring signals of the respective colors.

### (Acquisition of Green Color Signal by Organic Photoelectric Conversion Section 20)

First, the green light of the pieces of light having entered the imaging element 10 is selectively detected (absorbed) and photoelectrically converted by the organic photoelectric conversion section 20.

The organic photoelectric conversion section 20 is coupled to the gate Gamp of the amplifier transistor AMP and the floating diffusion FD1 through the through electrode 34. Thus, the electron of an electron-hole pair generated by the organic photoelectric conversion section 20 is taken out from the lower electrode 21 side, transferred to the second surface 30B side of the semiconductor substrate 30 through the through electrode 34, and accumulated in the floating diffusion FD1. At the same time as this, the amplifier transistor AMP modulates the amount of electric charge generated by the organic photoelectric conversion section 20 to a voltage.

In addition, the reset gate Grst of the reset transistor RST is disposed next to the floating diffusion FD1. This causes the reset transistor RST to reset the electric charge accumulated in the floating diffusion FD1.

Here, the organic photoelectric conversion section 20 is coupled to not only the amplifier transistor AMP, but also the floating diffusion FD1 through the through electrode 34, allowing the reset transistor RST to easily reset the electric charge accumulated in the floating diffusion FD1.

In contrast, in a case where the through electrode 34 and the floating diffusion FD1 are not coupled, it is difficult to reset the electric charge accumulated in the floating diffusion FD1. A large voltage has to be applied to pull out the electric charge to the upper electrode 27 side. The photoelectric conversion layer 24 may be therefore damaged. In addition, a structure that allows for resetting in a short period of time leads to increased dark-time noise and results in a trade-off. This structure is thus difficult.

FIG. 14 illustrates an operation example of the imaging element 10. (A) illustrates the potential at the accumulation electrode 21B, (B) illustrates the potential at the floating diffusion FD1 (readout electrode 21A), and (C) illustrates the potential at the gate (Gsel) of the reset transistor TR1rst. In the imaging element 10, voltages are individually applied to the readout electrode 21A and the accumulation electrode 21B.

In the imaging element 10, the drive circuit applies a potential V1 to the readout electrode 21A and applies a potential V2 to the accumulation electrode 21B in an accumulation period. Here, it is assumed that the potentials V1 and V2 satisfy V2>V1. This causes electric charge (electrons here) generated through photoelectric conversion to be drawn to the accumulation electrode 21B and accumulated in the region of the electric charge accumulation layer 23 opposed to the accumulation electrode 21B (accumulation period). Additionally, the value of the potential in the region of the electric charge accumulation layer 23 opposed to the accumulation electrode 21B becomes more negative with the passage of time of photoelectric conversion. It is to be noted that holes are sent from the upper electrode 27 to the drive circuit.

In the imaging element 10, a reset operation is performed in the latter half of the accumulation period. Specifically, at a timing t1, a scanning section changes the voltage of a reset signal RST from the low level to the high level. This turns on the reset transistor TR1rst in the unit pixel P. As a result, the voltage of the floating diffusion FD1 is set to the power supply line VDD and the voltage of the floating diffusion FD1 is reset (reset period).

After the reset operation is completed, the electric charge is read out. Specifically, the drive circuit applies a potential V3 to the readout electrode 21A and applies a potential V4 to the accumulation electrode 21B at a timing t2. Here, it is assumed that the potentials V3 and V4 satisfy V3<V4. This causes the electric charge (electrons here) accumulated in the region corresponding to the accumulation electrode 21B to be read out from the readout electrode 21A to the floating diffusion FD1. In other words, the electric charge accumulated in the electric charge accumulation layer 23 is read out to the controller (transfer period).

The drive circuit applies a potential V1 to the readout electrode 21A and applies the potential V2 to the accumulation electrode 21B again after the readout operation is completed. This causes electric charge (electrons here) generated through photoelectric conversion to be drawn to the accumulation electrode 21B and accumulated in the region of the photoelectric conversion layer 24 opposed to the accumulation electrode 21B (accumulation period).

### (Acquisition of Blue Color Signal and Red Color Signal by Inorganic Photoelectric Conversion Sections 32B and 32R)

Subsequently, the blue light and the red light of the pieces of light having passed through the organic photoelectric conversion section 20 are respectively absorbed and photoelectrically converted in order by the inorganic photoelectric conversion section 32B and the inorganic photoelectric conversion section 32R. In the inorganic photoelectric conversion section 32B, the electrons corresponding to the incident blue light are accumulated in an n region of the inorganic photoelectric conversion section 32B and the accumulated electrons are transferred to the floating diffusion FD2 by the transfer transistor Tr2. Similarly, in the inorganic photoelectric conversion section 32R, the electrons corresponding to the incident red light are accumulated in an n region of the inorganic photoelectric conversion section 32R and the accumulated electrons are transferred to the floating diffusion FD3 by the transfer transistor Tr3.

### 1-3. Workings and Effects

In the imaging element 10 according to the present embodiment, the work function adjustment layer 25 and the electron injection promoting layer 26 having a predetermined energy level are stacked in this order from the photoelectric conversion layer 24 side between the photoelectric conversion layer 24 and the upper electrode 27. The work function adjustment layer 25 includes at least one of a carbon-containing compound having a greater electron affinity than the work function of the lower electrode 21 or an inorganic compound having a greater work function than the work function of the lower electrode 21. The electron injection promoting layer 26 has an energy level that causes the absolute value B of the difference between the HOMO level and the Fermi level of the upper electrode 27 to be greater than or equal to the absolute value A of the difference between the LUMO level (LUMO2) calculated from the optical band gap and the Fermi level. Alternatively, the electron injection promoting layer 26 has an in-gap level having a state density of 1/10000 or more as compared with the HOMO level near the Fermi level of the upper electrode 27. This promotes electrons to be injected from the upper electrode 27 to the work function adjustment layer 25. The following describes this.

In an imaging device that separately extracts signals of B/G/R from one pixel, the electric charge generated in the semiconductor substrate is temporarily accumulated in each of photoelectric conversion sections (photodiodes PD1 and PD2) formed in the semiconductor substrate and then transferred to the corresponding floating diffusions FD as described above. This makes it possible to fully deplete each of the photoelectric conversion sections. In contrast, the electric charge resulting from photoelectric conversion by an organic photoelectric conversion section disposed, for example, above the semiconductor substrate is directly accumulated in the floating diffusion FD provided in the semiconductor substrate through a vertical transfer path provided in the semiconductor substrate. This makes it difficult to fully deplete the photoelectric conversion layer, consequently increasing kTC noise and degenerating random noise. This leads to lower image quality in imaging.

As a method of solving this issue, an imaging element has been devised that is provided with an electrode for electric charge accumulation. The electrode for electric charge accumulation is disposed to be spaced apart from one (e.g., lower electrode) of paired electrodes disposed to be opposed to each other with a photoelectric conversion layer interposed in between. In addition, the electrode for electric charge accumulation is opposed to a photoelectric conversion layer with an insulating layer interposed in between. In this imaging element, the electric charge generated in the photoelectric conversion layer is accumulated in a region opposed to the electrode for electric charge accumulation in the photoelectric conversion layer. The accumulated electric charge is transferred and read out to an electric charge readout electrode side as appropriate. This makes it possible to fully deplete the electric charge accumulation section at the start of exposure, thereby suppressing kTC noise and improving image quality in imaging. In addition, such an imaging element is provided with a semiconductor layer in which metal oxide is used that is, for example, an n-type semiconductor such as IGZO in a lower layer of the photoelectric conversion layer. This makes it possible to prevent electric charge from being recombined during electric charge accumulation and further increase the efficiency of transferring the accumulated electric charge to the electric charge readout electrode.

The use of metal oxide that is an n-type semiconductor for the semiconductor layer, however, raises an issue about the rapid transfer and accumulation of electrons generated by light irradiation in the photoelectric conversion layer to and in the semiconductor layer. It is possible to solve this issue by increasing the photoresponsivity of the photoelectric conversion layer.

In contrast, in the present embodiment, the electron injection promoting layer 26 is provided between the work function adjustment layer 25 and the upper electrode 27 provided on the photoelectric conversion layer 24. The electron injection promoting layer 26 has the following value as the energy level after being joined to the upper electrode 27. In a case where the electron injection promoting layer 26 is joined to the upper electrode 27, the HOMO level and the LUMO level shift in a deep direction in accordance with the Fermi level of the upper electrode 27. The Fermi level of the upper electrode 27 and the LUMO level of the electron injection promoting layer 26 come closer to each other from the perspective of energy. Specifically, in the present embodiment, the electron injection promoting layer 26 is provided in which the absolute value B of the difference between the HOMO level and the Fermi level of the upper electrode 27 is greater than or equal to the absolute value A of the difference between the LUMO level (LUMO2) calculated from the optical band gap and the Fermi level or the electron injection promoting layer 26 is provided that has an in-gap level having a state density of 1/10000 or more as compared with the HOMO level near the Fermi level. This promotes the injection of electrons to be injected from the upper electrode 27. In other words, the carrier density of electrons is increased at the interface between the work function adjustment layer 25 and the organic layer including the photoelectric conversion layer 24 adjacent to the work function adjustment layer 25.

Thus, in the imaging element 10 according to the present embodiment, the recombination of holes and potentials is promoted at the interface between the work function adjustment layer 25 and the organic layer including the photoelectric conversion layer 24 adjacent to the work function adjustment layer 25. This makes it possible to increase the photoresponsivity of the photoelectric conversion layer 24.

### 2. APPLICATION EXAMPLES

### Application Example 1

FIG. 15 illustrates an overall configuration of an imaging device (imaging device 1) in which the imaging element 10 described in the embodiment described above is used for each of the pixels. This imaging device 1 is a CMOS image sensor. The imaging device 1 includes the pixel section 1a as an imaging area and the peripheral circuit portion 130 in a peripheral region of this pixel section 1a on the semiconductor substrate 30. The peripheral circuit portion 130 includes, for example, a row scanning section 131, a horizontal selection section 133, a column scanning section 134, and a system control section 132.

The pixel section 1a includes, for example, the plurality of unit pixels P (each corresponding to the imaging element 10) that is two-dimensionally disposed in a matrix. These unit pixels P are provided, for example, with a pixel drive line Lread (specifically, a row selection line and a reset control line) for each of the pixel rows and provided with a vertical signal line Lsig for each of the pixel columns. The pixel drive line Lread transmits drive signals for reading out signals from the pixels. One end of the pixel drive line Lread is coupled to the output end of the row scanning section 131 corresponding to each of the rows.

The row scanning section 131 is a pixel drive section that includes a shift register, an address decoder, and the like and drives the respective unit pixels P of the pixel section 1a, for example, row by row. Signals outputted from the respective unit pixels P in the pixel rows selectively scanned by the row scanning section 131 are supplied to the horizontal selection section 133 through the respective vertical signal lines Lsig. The horizontal selection section 133 includes an amplifier, a horizontal selection switch, and the like provided for each of the vertical signal lines Lsig.

The column scanning section 134 includes a shift register, an address decoder, and the like. The column scanning section 134 drives the respective horizontal selection switches of the horizontal selection section 133 in order while scanning the horizontal selection switches. The selective scanning by this column scanning section 134 causes signals of the respective pixels transmitted through each of the vertical signal lines Lsig to be outputted to a horizontal signal line 135 in order and causes the signals to be transmitted to the outside of the semiconductor substrate 30 through the horizontal signal line 135.

The circuit portion including the row scanning section 131, the horizontal selection section 133, the column scanning section 134, and the horizontal signal line 135 may be formed directly on the semiconductor substrate 30 or may be provided on external control IC. In addition, the circuit portion thereof may be formed in another substrate coupled by a cable or the like.

The system control section 132 receives a clock supplied from the outside of the semiconductor substrate 30, data for an instruction about an operation mode, and the like and also outputs data such as internal information of the imaging device 1. The system control section 132 further includes a timing generator that generates a variety of timing signals and controls the driving of the peripheral circuits such as the row scanning section 131, the horizontal selection section 133, and the column scanning section 134 on the basis of the variety of timing signals generated by the timing generator.

### Application Example 2

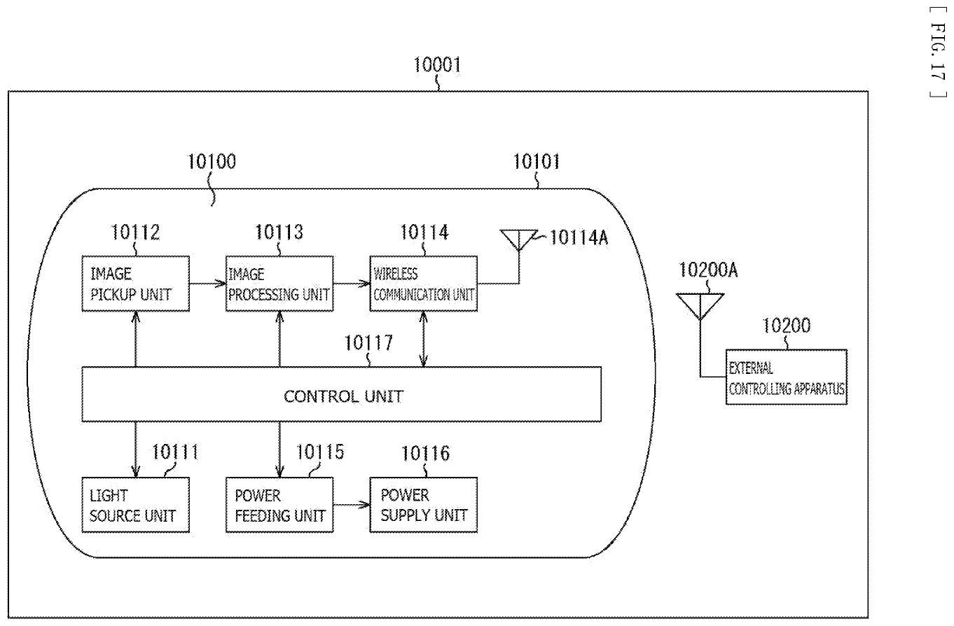

The imaging device 1 described above is applicable, for example, to any type of electronic apparatus with an imaging function including a camera system such as a digital still camera and a video camera, a mobile phone having an imaging function, and the like. FIG. 16 illustrates a schematic configuration of an electronic apparatus 2 (camera) as an example thereof. This electronic apparatus 2 is, for example, a video camera that is able to shoot a still image or a moving image. The electronic apparatus 2 includes the imaging device 1, an optical system (optical lens) 310, a shutter device 311, a drive section 313 that drives the imaging device 1 and the shutter device 311, and a signal processing section 312.

The optical system 310 guides image light (incident light) from a subject to the pixel section 1a of the imaging device 1. This optical system 310 may include a plurality of optical lenses. The shutter device 311 controls a period of time in which the imaging device 1 is irradiated with light and a period of time in which light is blocked. The drive section 313 controls a transfer operation of the imaging device 1 and a shutter operation of the shutter device 311. The signal processing section 312 performs various kinds of signal processing on signals outputted from the imaging device 1. An image signal Dout subjected to the signal processing is stored in a storage medium such as a memory or outputted to a monitor or the like.

Further, the imaging device 1 described above is also applicable to the following electronic apparatuses (a capsule type endoscope 10100 and a mobile body such as a vehicle).

### 3. PRACTICAL APPLICATION EXAMPLES

### (Example of Practical Application to In-Vivo Information Acquisition System)

Further, the technology (the present technology) according to the present disclosure is applicable to a variety of products. For example, the technology according to the present disclosure may be applied to an endoscopic surgery system.

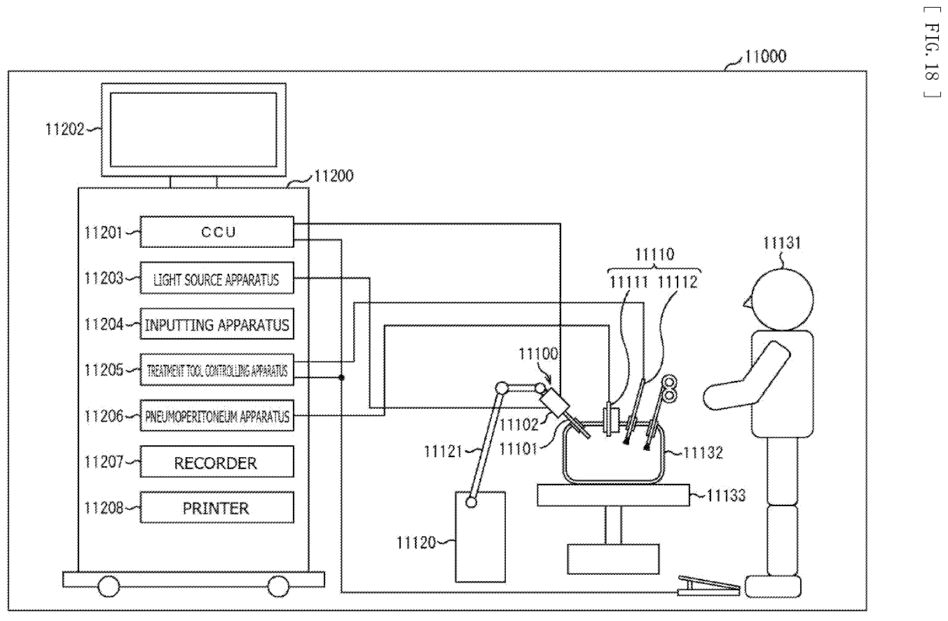

FIG. 17 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 17, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

The example of the in-vivo information acquisition system to which the technology according to the present disclosure may be applied has been described above. The technology according to the present disclosure may be applied, for example, to the image pickup unit 10112 among the components described above. This increases the detection accuracy.

### (Example of Practical Application to Endoscopic Surgery System)

The technology (the present technology) according to the present disclosure is applicable to a variety of products. For example, the technology according to the present disclosure may be applied to an endoscopic surgery system.

FIG. 18 is a view depicting an example of a schematic configuration of an endoscopic surgery system to which the technology according to an embodiment of the present disclosure (present technology) can be applied.

In FIG. 18, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

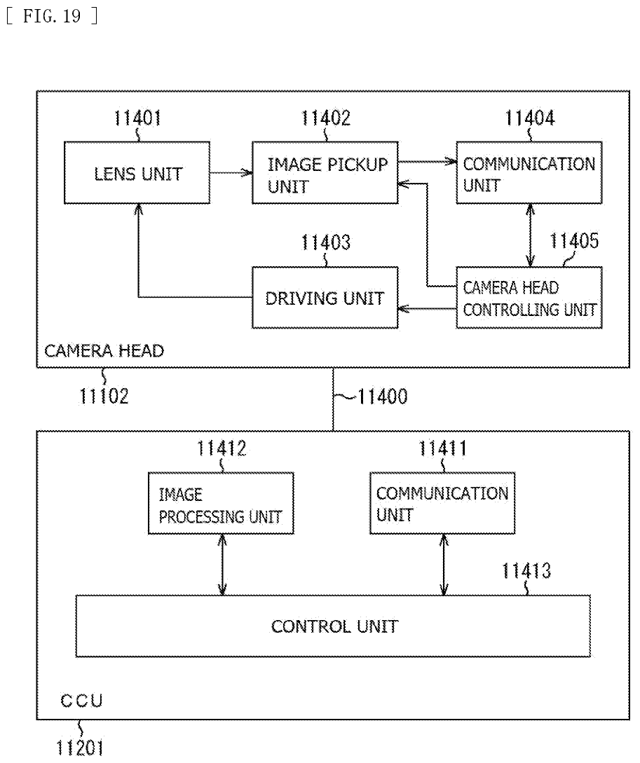

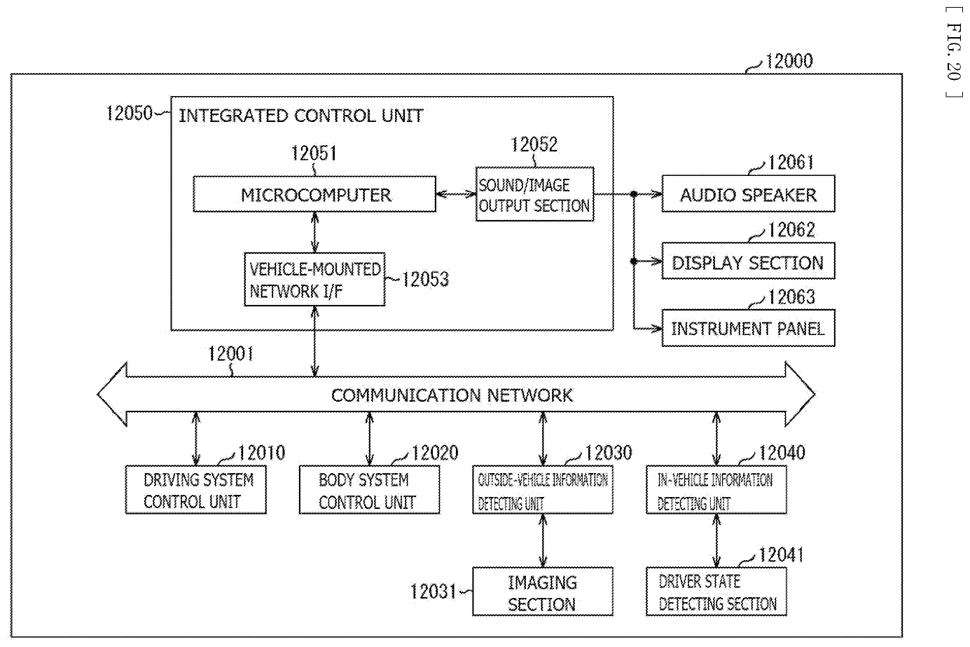

FIG. 19 is a block diagram depicting an example of a functional configuration of the camera head 11102 and the CCU 11201 depicted in FIG. 18.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The example of the endoscopic surgery system to which the technology according to the present disclosure may be applied has been described above. The technology according to the present disclosure may be applied to the image pickup unit 11402 among the components described above. The application of the technology according to the present disclosure to the image pickup unit 11402 increases the detection accuracy.

It is to be noted that the endoscopic surgery system has been described here as an example, but the technology according to the present disclosure may be additionally applied, for example, to a microscopic surgery system or the like.

### (Example of Practical Application to Mobile Body)

The technology according to the present disclosure is applicable to a variety of products. For example, the technology according to the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, a construction machine, or an agricultural machine (tractor).

FIG. 20 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are illustrated as the output device. The display section 12062 may, for example, include at least one of an on-board display and a head-up display.

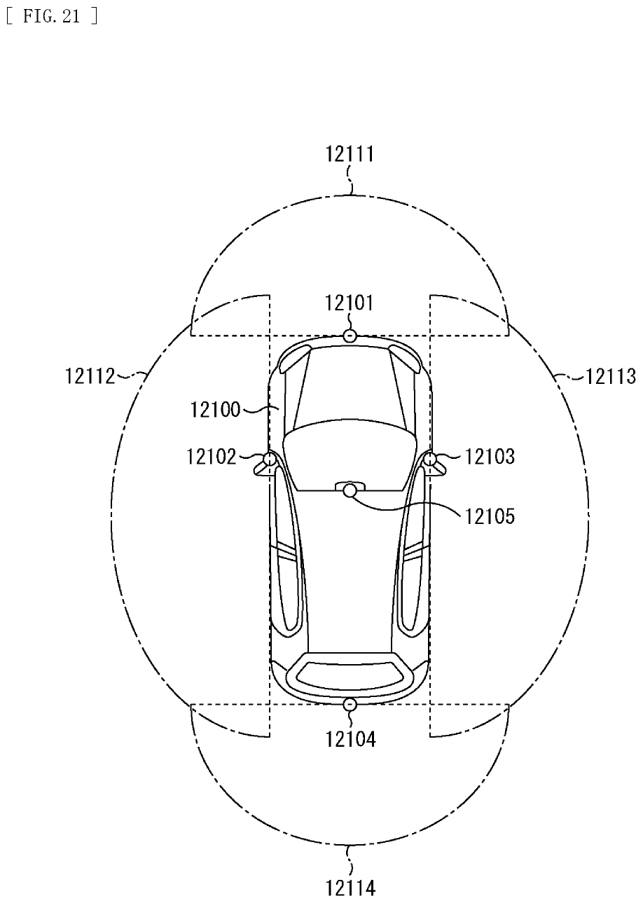

FIG. 21 is a diagram depicting an example of the installation position of the imaging section 12031.

In FIG. 21, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

### 4. WORKING EXAMPLES

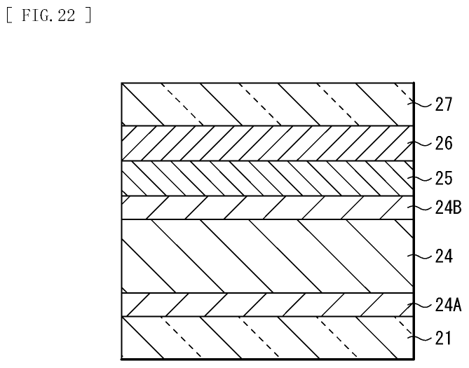

Next, working examples of the present disclosure are described in detail. An imaging element having the cross-sectional configuration illustrated in FIG. 22 was fabricated below as a device sample and the device characteristics thereof were evaluated.

### Experimental Example 1

An ITO film having a thickness of 100 nm was formed on a quartz substrate by using a sputtering apparatus. This ITO film was patterned by photolithography and etching to form an ITO electrode (lower electrode 21). Subsequently, the quartz substrate provided with the ITO electrode was cleaned by UV/ozone treatment. After that, the quartz substrate was moved into a vacuum evaporation machine and organic layers were stacked in order on the quartz substrate under a reduced pressure of 1×10⁻⁵ Pa or less while rotating a substrate holder. First, a hole blocking layer 24A was formed on the lower electrode 21 by using the NDI-35 represented by the following formula (1) at a substrate temperature of 0° C. to have a thickness of 10 nm. Next, films of the F6-OPh-26F2 represented by the following formula (2), the BP-rBDT represented by the following formula (3), and a fullerene C₆₀ were formed at a substrate temperature of 40° C. at film formation rates of 0.50 Å/second, 0.50 Å/second, and 0.25 Å/second, respectively, to offer a thickness of 230 nm as a mixture layer and form the photoelectric conversion layer 24. Subsequently, a film of the PC-ID represented by the following formula (4) was formed at a substrate temperature of 0° C. to have a thickness of 10 nm and an electron blocking layer 24B was formed. After that, a film of the HATCN represented by the following formula (5) was formed to have a thickness of 10 nm and the work function adjustment layer 25 was formed. Next, a film of the NDI-35 represented by the following formula (1) was formed to have a thickness of 2 nm and the electron injection promoting layer 26 was formed. Finally, the quartz substrate was moved to a sputtering apparatus. An ITO film was formed on the electron injection promoting layer 26 to have a thickness of 50 nm and the upper electrode 27 was formed. A sample (experimental example 1) having a photoelectric conversion region of 1 mm×1 mm was fabricated in the fabrication method described above. The fabricated device sample was subjected to annealing treatment at 150° C. for 210 minutes under a nitrogen (N₂) atmosphere.

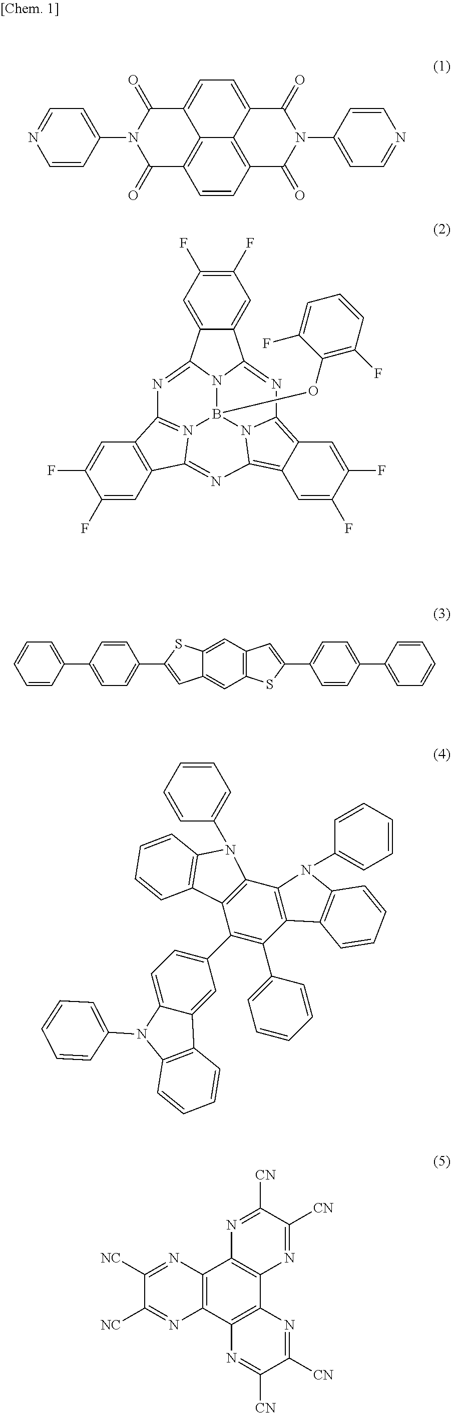

### Experimental Example 2

In an experimental example 2, a device sample (experimental example 2) was fabricated by using a method similar to that of the experimental example 1 except that the electron injection promoting layer 26 was not formed.

### Experimental Example 3

In an experimental example 3, a method similar to that of the experimental example 1 was used to fabricate a device sample (experimental example 3) except that the photoelectric conversion layer 24 was formed by forming films of the BP-rBDT represented by the formula (3) described above and a fullerene C₆₀ at a substrate temperature of 40° C. at film formation rates of 0.50 Å/second and 0.50 Å/second, respectively, to offer a thickness of 230 nm as a mixture layer.

### Experimental Example 4

In an experimental example 4, a device sample (experimental example 4) was fabricated by using a method similar to that of the experimental example 3 except that the electron injection promoting layer 26 was not formed.

### Experimental Example 5

In an experimental example 5, a method similar to that of the experimental example 1 was used to fabricate a device sample (experimental example 5) except that the electron injection promoting layer 26 was formed by using the CzBDF represented by the following formula (6) to have a thickness of 2 nm.

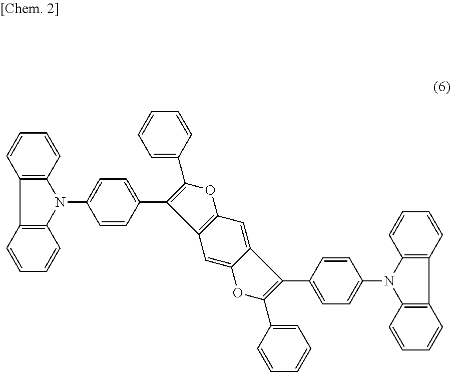 [SMILES: c1ccc(-c2oc3cc4c(-c5ccc(-n6c7ccccc7c7ccccc76)cc5)c(-c5ccccc5)oc4cc3c2-c2ccc(-n3c4ccccc4c4ccccc43)cc2)cc1]

### Experimental Example 6

In an experimental example 6, a method similar to that of the experimental example 1 was used to fabricate a device sample (experimental example 6) except that the electron injection promoting layer 26 was formed by using the NBphen represented by the following formula (7) to have a thickness of 2 nm.

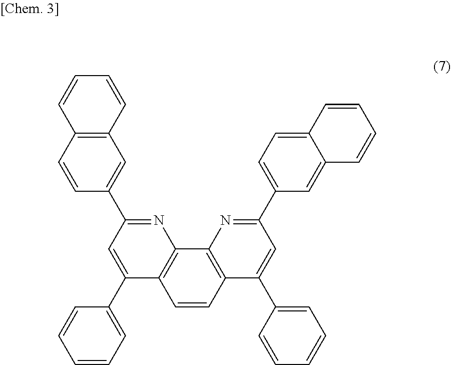 [SMILES: c1ccc(-c2cc(-c3ccc4ccccc4c3)nc3c2ccc2c(-c4ccccc4)cc(-c4ccc5ccccc5c4)nc23)cc1]

### Experimental Example 7

In an experimental example 7, a method similar to that of the experimental example 1 was used to fabricate a device sample (experimental example 7) except that the electron injection promoting layer 26 was formed by using the BCP represented by the following formula (8) to have a thickness of 2 nm.

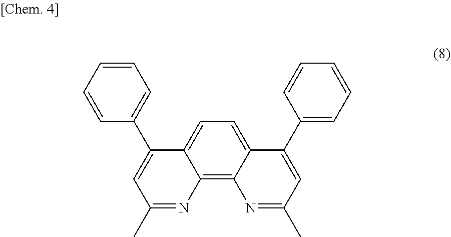 [SMILES: Cc1cc(-c2ccccc2)c2ccc3c(-c4ccccc4)cc(C)nc3c2n1]

### Experimental Example 8

In an experimental example 8, a method similar to that of the experimental example 1 was used to fabricate a device sample (experimental example 8) except that the electron injection promoting layer 26 was formed by using LiF to have a thickness of 2 nm.

The energy levels of the electron injection promoting layers 26 formed in the experimental examples 1 to 8 described above were analyzed by using the following evaluation methods. In addition, the dark currents, the external quantum efficiency (EQE), and the photoresponsivity of the respective device samples in the experimental examples 1 to 6 were evaluated. These are tabulated in Table 1.

### (Evaluation of Energy Level)

A sample in which an ITO film and a single film of each of materials to be measured were formed on a quartz substrate was formed and the respective energy levels were obtained by using UPS and LEIPS.

### (Evaluation of Dark Currents)

As the evaluation of the dark currents, a current value was measured that was obtained in a dark state in a case where a bias voltage to be applied between electrodes of a photoelectric conversion element is controlled by using a semiconductor parameter analyzer and a voltage to be applied to the lower electrode 21 was set to −2.6 V as compared with the upper electrode 27.

### (Evaluation of External Photoelectric Conversion Efficiency)

As the evaluation of the external photoelectric conversion efficiency, the effective number of carriers was obtained by subtracting a dark current value from a light current value that was obtained in a case where a device sample was irradiated with 1.62 μW/cm² of light having a wavelength of 560 nm from a light source through a filter, a bias voltage to be applied between electrodes of a device sample was controlled by using a semiconductor parameter analyzer, and a voltage to be applied to the lower electrode 21 was set to 2.6 V as compared with the upper electrode 27. The external photoelectric conversion efficiency was calculated by dividing this by the number of incident photons. The characteristic values in the experimental example 2 were standardized as 1 for relative comparison.

### (Evaluation of Photoresponsivity)

As the evaluation of the photoresponsivity, decreasing current values were measured after light irradiation in a case where a bias voltage to be applied between electrodes of a device sample was controlled by using a semiconductor parameter analyzer and a voltage to be applied to the lower electrode 21 was set to 2.6 V as compared with the upper electrode 27. After light irradiation, the current values for 1 ms to 110 ms after light is blocked are integrated and evaluated as relative values. A smaller numerical value means more favorable photoresponsivity.

TABLE 1

| | | electron | | | | | | | | |
|---|---|---|---|---|---|---|---|---|---|---|
| | | injection | | | | | | standardized | standardized | |
| | device | promoting | Gap State/ | | | | | dark current | EQE | |
| | structure | layer | HOMO Int. | B/A | B/A’ | b/a | b/a’ | (A/cm²) | (%) | photoresponsivity |
| experimental | green OPD | NDI35 | 2 × 10⁻³ | 7.2 | 9.0 | 5.4 | 19 | 1.50 | 1.04 | 0.77 |
| example 1 | | | | | | | | | | |
| experimental | green OPD | none | — | — | — | — | — | 1.00 | 1.00 | 1.00 |
| example 2 | | | | | | | | | | |
| experimental | blue OPD | NDI35 | 2 × 10⁻ [symbol] | 7.2 | 9.0 | 5.4 | 19 | 6.65 | 0.46 | 0.34 |
| example 3 | | | | | | | | | | |
| experimental | blue OPD | none | — | — | — | — | — | 0.37 | 0.43 | 0.66 |
| example 4 | | | | | | | | | | |
| experimental | green OPD | C [symbol] BDF | 2 × 10⁻ [symbol] | 1.4 | 1.0 | 0.5 | 0.4 | 0.69 | 1.03 | 1.37 |
| example 5 | | | | | | | | | | |
| experimental | green OPD | NBPhen | 3.7 × 10⁻⁴ | 1.8 | 1.3 | 3.4 | 2.0 | 1.10 | 0.96 | 0.85 |
| example 6 | | | | | | | | | | |
| experimental | green OPD | BCP | 3 × 10⁻⁴ | 1.6 | 1.1 | 3.0 | 1.7 | 1.14 | 0.96 | 0.90 |
| example 7 | | | | | | | | | | |
| experimental | green OPD | L [symbol] | 4 × 10⁻ [symbol] | 6.1 | 6.1 | 30 | 30 | 0.90 | 0.98 | 0.60 |
| example 8 | | | | | | | | | | |

[symbol]

indicates data missing or illegible when filed

As can be seen from Table 1, the photoresponsivity tends to be improved in a case of an in-gap level having a state density of more than 1/10000 as compared with the HOMO level. In addition, as the values of B/A, B/A′, a/b, and a/b′ are larger, the photoresponsivity tends to be improved.

Although the description has been given with reference to the embodiment and the working examples and the application examples and the practical application examples, the contents of the present disclosure are not limited to the embodiment and the like described above. A variety of modifications are possible. For example, in the embodiment described above, an imaging element has a configuration in which the organic photoelectric conversion section 20 that detects green light and the inorganic photoelectric conversion sections 32B and 32R that respectively detect blue light and red light are stacked. The contents of the present disclosure are not, however, limited to such a structure. In other words, the organic photoelectric conversion section may detect the red light or the blue light or the inorganic photoelectric conversion sections may each detect the green light.

In addition, the number of these organic photoelectric conversion sections and inorganic photoelectric conversion sections or the proportion thereof is not limited. The two or more organic photoelectric conversion sections may be provided or color signals of a plurality of colors may be obtained with the organic photoelectric conversion section alone.

Further, in the embodiment described above, the example has been described in which the two electrodes of the readout electrode 21A and the accumulation electrode 21B are provided as a plurality of electrodes included in the lower electrode 21, but there may be additionally provided three or four or more electrodes such as a transfer electrode or a discharge electrode.

Furthermore, in the embodiment described above, the example has been described in which the lower electrode 21 is formed by using a plurality of electrodes. The present technology, however, allows even an imaging element including a lower electrode including one electrode to achieve a similar effect.

It is to be noted that the effects described herein are merely examples, but are not limitative. In addition, there may be other effects.

It is to be noted that the present disclosure may have the following configurations. The present technology having the following configurations provides the first semiconductor layer between the second electrode and the organic layer. The second electrode is disposed to be opposed to the first electrode with the organic layer interposed in between. The organic layer includes at least the photoelectric conversion layer. The first semiconductor layer includes at least one of the carbon-containing compound or the inorganic compound. The carbon-containing compound has a greater electron affinity than the work function of the first electrode. The inorganic compound has a greater work function than the work function of the first electrode. Further, the present technology having the following configurations provides the second semiconductor layer between the second electrode and the first semiconductor layer. The second semiconductor layer has the absolute value B of the difference between the HOMO level and the Fermi level of the second electrode or has, near the Fermi level, the in-gap level having a state density of 1/10000 or more as compared with the HOMO level. The absolute value B is greater than or equal to the absolute value A of the difference between the first LUMO level and the Fermi level. The first LUMO level is calculated from the optical band gap. This promotes electrons to be injected from the second electrode to the first semiconductor layer and makes it possible to increase the photoresponsivity.

(1)

An imaging element including:

a first electrode;

a second electrode that is disposed to be opposed to the first electrode;

an organic layer that is provided between the first electrode and the second electrode, the organic layer including at least a photoelectric conversion layer;

a first semiconductor layer that is provided between the second electrode and the organic layer, the first semiconductor layer including at least one of a carbon-containing compound or an inorganic compound, the carbon-containing compound having a greater electron affinity than a work function of the first electrode, the inorganic compound having a greater work function than the work function of the first electrode; and

a second semiconductor layer that is provided between the second electrode and the first semiconductor layer, the second semiconductor layer having an absolute value B of a difference between a HOMO (Highest Occupied Molecular Orbital) level and a Fermi level of the second electrode or having, near the Fermi level, an in-gap level having a state density of 1/10000 or more as compared with the HOMO level, the absolute value B being greater than or equal to an absolute value A of a difference between a first LUMO (Lowest Unoccupied Molecular Orbital) level and the Fermi level, the first LUMO level being calculated from an optical band gap.

(2)

The imaging element according to (1), in which the absolute value B of the difference between the HOMO level of the second semiconductor layer and the Fermi level is greater than an absolute value A′ of a difference between a second LUMO level and the Fermi level.

(3)

The imaging element according to (1) or (2), in which an absolute value b of a difference between the HOMO level and the in-gap level of the second semiconductor layer is two or more times as great as an absolute value a of a difference between the first LUMO level and the in-gap level.

(4)

The imaging element according to any one of (1) to (3), in which an absolute value b of a difference between the HOMO level and the in-gap level of the second semiconductor layer is 1.5 or more times as great as an absolute value a′ of a difference between a second LUMO level and the in-gap level.

(5)

The imaging element according to any one of (1) to (4), in which a work function of the second electrode is smaller than a work function of the first semiconductor layer.

(6)

The imaging element according to any one of (1) to (5), in which

the organic layer adjacent to the first semiconductor layer includes an organic material, and

a HOMO level of the organic material has a shallower energy level than a work function of the first semiconductor layer.

(7)

The imaging element according to any one of (1) to (6), in which

the organic layer adjacent to the first semiconductor layer includes an organic material, and

the organic material has a glass transition point of more than 100° C.

(8)

The imaging element according to any one of (1) to (7), in which the first semiconductor layer has a light absorptivity of 10% or less for visible light.

(9)

The imaging element according to any one of (1) to (8), further including a third semiconductor layer between the first electrode and the organic layer, the third semiconductor layer including an oxide semiconductor material, in which

a lowest edge of a conduction band of the oxide semiconductor material has a shallower energy level than the work function of the first electrode.

(10)

The imaging element according to any one of (1) to (9), in which the first electrode includes a plurality of electrodes that is independent of each other.

(11)

The imaging element according to (10), in which the first electrode includes an electric charge readout electrode and an electric charge accumulation electrode as the plurality of electrodes.

(12)

The imaging element according to (11), in which voltages are individually applied to the plurality of respective electrodes.

(13)

The imaging element according to (11) or (12), further including:

a third semiconductor layer between the first electrode and the organic layer, the third semiconductor layer including an oxide semiconductor material; and

an insulating layer between the first electrode and the third semiconductor layer, in which

the electric charge readout electrode is electrically coupled to the third semiconductor layer through an opening provided in the insulating layer.

(14)

The imaging element according to any one of (1) to (13), in which the first electrode is disposed on the organic layer on an opposite side to a light incidence surface.

(15)

The imaging element according to any one of (1) to (14), in which an organic photoelectric conversion section and one or more inorganic photoelectric conversion sections are stacked, the organic photoelectric conversion section including the one or more organic layers, the one or more inorganic photoelectric conversion sections each performing photoelectric conversion in a wavelength range different from a wavelength range of the organic photoelectric conversion section.

(16)

The imaging element according to (15), in which

the inorganic photoelectric conversion section is formed to be buried in a semiconductor substrate, and

the organic photoelectric conversion section is formed on a first surface side of the semiconductor substrate.

(17)

The imaging element according to (16), in which a multilayer wiring layer is formed on a second surface side of the semiconductor substrate.

(18)

The imaging element according to (16) or (17), in which

the organic photoelectric conversion section photoelectrically converts green light, and

an inorganic photoelectric conversion section that photoelectrically converts blue light and an inorganic photoelectric conversion section that photoelectrically converts red light are stacked inside the semiconductor substrate.

(19)

An imaging device including

a plurality of pixels that is each provided with one or more imaging elements, in which

the imaging elements each include
a first electrode,
a second electrode that is disposed to be opposed to the first electrode,
an organic layer that is provided between the first electrode and the second electrode, the organic layer including at least a photoelectric conversion layer,
a first semiconductor layer that is provided between the second electrode and the organic layer, the first semiconductor layer including at least one of a carbon-containing compound or an inorganic compound, the carbon-containing compound having a greater electron affinity than a work function of the first electrode, the inorganic compound having a greater work function than the work function of the first electrode, and
a second semiconductor layer that is provided between the second electrode and the first semiconductor layer, the second semiconductor layer having an absolute value B of a difference between a HOMO (Highest Occupied Molecular Orbital) level and a Fermi level of the second electrode or having, near the Fermi level, an in-gap level having a state density of 1/10000 or more as compared with the HOMO level, the absolute value B being greater than or equal to an absolute value A of a difference between a first LUMO (Lowest Unoccupied Molecular Orbital) level and the Fermi level, the first LUMO level being calculated from an optical band gap.
   (20)

The imaging device according to (19), in which the first electrode is formed for each of pixels and includes the plurality of electrodes in the pixel.

This application claims the priority on the basis of Japanese Patent Application No. 2020-012779 filed with Japan Patent Office on Jan. 29, 2020, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. An imaging element comprising:
a first electrode;
a second electrode that is disposed to be opposed to the first electrode;
an organic layer that is provided between the first electrode and the second electrode, the organic layer including at least a photoelectric conversion layer;
a first semiconductor layer that is provided between the second electrode and the organic layer, the first semiconductor layer including at least one of a carbon-containing compound or an inorganic compound, the carbon-containing compound having a greater electron affinity than a work function of the first electrode, the inorganic compound having a greater work function than the work function of the first electrode; and
a second semiconductor layer that is provided between the second electrode and the first semiconductor layer, the second semiconductor layer having an absolute value B of a difference between a HOMO (Highest Occupied Molecular Orbital) level and a Fermi level of the second electrode or having, near the Fermi level, an in-gap level having a state density of 1/10000 or more as compared with the HOMO level, the absolute value B being greater than or equal to an absolute value A of a difference between a first LUMO (Lowest Unoccupied Molecular Orbital) level and the Fermi level, the first LUMO level being calculated from an optical band gap.

2. The imaging element according to claim 1, wherein the absolute value B of the difference between the HOMO level of the second semiconductor layer and the Fermi level is greater than an absolute value A′ of a difference between a second LUMO level and the Fermi level.

3. The imaging element according to claim 1, wherein an absolute value b of a difference between the HOMO level and the in-gap level of the second semiconductor layer is two or more times as great as an absolute value a of a difference between the first LUMO level and the in-gap level.

4. The imaging element according to claim 1, wherein an absolute value b of a difference between the HOMO level and the in-gap level of the second semiconductor layer is 1.5 or more times as great as an absolute value a′ of a difference between a second LUMO level and the in-gap level.

5. The imaging element according to claim 1, wherein a work function of the second electrode is smaller than a work function of the first semiconductor layer.

6. The imaging element according to claim 1, wherein
the organic layer adjacent to the first semiconductor layer includes an organic material, and
a HOMO level of the organic material has a shallower energy level than a work function of the first semiconductor layer.

7. The imaging element according to claim 1, wherein
the organic layer adjacent to the first semiconductor layer includes an organic material, and
the organic material has a glass transition point of more than 100° C.

8. The imaging element according to claim 1, wherein the first semiconductor layer has a light absorptivity of 10% or less for visible light.

9. The imaging element according to claim 1, further comprising a third semiconductor layer between the first electrode and the organic layer, the third semiconductor layer including an oxide semiconductor material, wherein
a lowest edge of a conduction band of the oxide semiconductor material has a shallower energy level than the work function of the first electrode.

10. The imaging element according to claim 1, wherein the first electrode includes a plurality of electrodes that is independent of each other.

11. The imaging element according to claim 10, wherein the first electrode includes an electric charge readout electrode and an electric charge accumulation electrode as the plurality of electrodes.

12. The imaging element according to claim 11, wherein voltages are individually applied to the plurality of respective electrodes.

13. The imaging element according to claim 11, further comprising:
a third semiconductor layer between the first electrode and the organic layer, the third semiconductor layer including an oxide semiconductor material; and
an insulating layer between the first electrode and the third semiconductor layer, wherein
the electric charge readout electrode is electrically coupled to the third semiconductor layer through an opening provided in the insulating layer.

14. The imaging element according to claim 1, wherein the first electrode is disposed on the organic layer on an opposite side to a light incidence surface.

15. The imaging element according to claim 1, wherein an organic photoelectric conversion section and one or more inorganic photoelectric conversion sections are stacked, the organic photoelectric conversion section including the one or more organic layers, the one or more inorganic photoelectric conversion sections each performing photoelectric conversion in a wavelength range different from a wavelength range of the organic photoelectric conversion section.

16. The imaging element according to claim 15, wherein
the inorganic photoelectric conversion section is formed to be buried in a semiconductor substrate, and
the organic photoelectric conversion section is formed on a first surface side of the semiconductor substrate.

17. The imaging element according to claim 16, wherein a multilayer wiring layer is formed on a second surface side of the semiconductor substrate.

18. The imaging element according to claim 16, wherein
the organic photoelectric conversion section photoelectrically converts green light, and
an inorganic photoelectric conversion section that photoelectrically converts blue light and an inorganic photoelectric conversion section that photoelectrically converts red light are stacked inside the semiconductor substrate.

19. An imaging device comprising
a plurality of pixels that is each provided with one or more imaging elements, wherein
the imaging elements each include
a first electrode,
a second electrode that is disposed to be opposed to the first electrode,
an organic layer that is provided between the first electrode and the second electrode, the organic layer including at least a photoelectric conversion layer,
a first semiconductor layer that is provided between the second electrode and the organic layer, the first semiconductor layer including at least one of a carbon-containing compound or an inorganic compound, the carbon-containing compound having a greater electron affinity than a work function of the first electrode, the inorganic compound having a greater work function than the work function of the first electrode, and
a second semiconductor layer that is provided between the second electrode and the first semiconductor layer, the second semiconductor layer having an absolute value B of a difference between a HOMO (Highest Occupied Molecular Orbital) level and a Fermi level of the second electrode or having, near the Fermi level, an in-gap level having a state density of 1/10000 or more as compared with the HOMO level, the absolute value B being greater than or equal to an absolute value A of a difference between a first LUMO (Lowest Unoccupied Molecular Orbital) level and the Fermi level, the first LUMO level being calculated from an optical band gap.

20. The imaging device according to claim 19, wherein the first electrode is formed for each of pixels and includes the plurality of electrodes in the pixel.
